(19) United States
(12) Patent Application Publication
(10) Pub. No.: US 2023/0343578 A1
(43) Pub. Date: Oct. 26, 2023

(54) SEMICONDUCTOR DEVICE MANUFACTURING METHOD AND WAFER STRUCTURAL OBJECT

(71) Applicant: ROHM CO., LTD., Kyoto-shi, Kyoto (JP)

(72) Inventor: Minoru NAKAGAWA, Kyoto-shi, Kyoto (JP)

(73) Assignee: ROHM CO., LTD., Kyoto-shi, Kyoto (JP)

(21) Appl. No.: 18/013,569

(22) PCT Filed: Aug. 30, 2021
(86) PCT No.: PCT/JP2021/031786

§ 371 Date: Dec. 29, 2022

(30) Foreign Application Priority Data
Sep. 17, 2020 (JP) 2020-156603

(51) Int. Cl. H01L 21/02; H01L 21/683; H01L 21/784

(52) U.S. Cl. CPC H01L 21/02013; H01L 21/6835; H01L 21/784; H01L 29/6606

(57) ABSTRACT

A semiconductor device manufacturing method includes a step which prepares a wafer source and a supporting member, a supporting step which supports the wafer source by the supporting member, and a wafer separating step in which the wafer source is cut in a horizontal direction from a thickness direction intermediate portion of the wafer source to separate, from the wafer source, a wafer structure which includes the supporting member and a wafer cut away from the wafer source.

### TECHNICAL FIELD

This application corresponds to Japanese Patent Application No. 2020-156603 filed with the Japan Patent Office on Sep. 17, 2020, the entire disclosure of which is incorporated herein by reference. The present invention relates to a semiconductor device manufacturing method and a wafer structure.

### BACKGROUND ART

Patent Literature 1 discloses a semiconductor device manufacturing method including a step of thinning a semiconductor wafer by grinding and a step of cutting out a plurality of semiconductor chips from the thinned semiconductor wafer.

### CITATION LIST

### Patent Literature

Patent Literature 1: Japanese Patent Application Publication No. 2010-016188

### SUMMARY OF INVENTION

### Technical Problem

A preferred embodiment of the present invention provides a semiconductor device manufacturing method capable of improving manufacturing efficiency and a wafer structure.

### Solution to Problem

A preferred embodiment of the present invention provides a semiconductor device manufacturing method including a step which prepares a wafer source and a supporting member, a supporting step which supports the wafer source by the supporting member, and a wafer separating step in which the wafer source is cut in a horizontal direction from a thickness direction intermediate portion of the wafer source to separate from the wafer source a wafer structure which includes the supporting member and a wafer cut away from the wafer source.

A preferred embodiment of the present invention provides a semiconductor device manufacturing method including a step which prepares a first semiconductor and a second semiconductor, a step in which the second semiconductor is bonded to the first semiconductor by a direct bonding method to form a semiconductor structure having an amorphous bonding layer between the first semiconductor and the second semiconductor, a step which forms a modified layer in the amorphous bonding layer by a laser light irradiation method and a step which cleaves the semiconductor structure with the modified layer as a starting point and separates the first semiconductor and the second semiconductor.

A preferred embodiment of the present invention provides a wafer structure which includes a first wafer, a second wafer which supports the first wafer and an amorphous bonding layer which is interposed between the first wafer and the second wafer and bonds the first wafer and the second wafer.

The aforementioned as well as yet other objects, features, and effects of the present invention will be made clear by the following description of the preferred embodiments with reference to the accompanying drawings.

### BRIEF DESCRIPTION OF DRAWINGS

FIG. 1 is a perspective view showing an SiC wafer source, a first supporting member and a second supporting member which are used in an SiC semiconductor device manufacturing method according to a first preferred embodiment of the present invention.

FIG. 2 is a flowchart showing one example of the SiC semiconductor device manufacturing method implemented with respect to the SiC wafer source.

FIG. 3A is a cross-sectional view for describing one example of the SiC semiconductor device manufacturing method implemented with respect to the SiC wafer source.

FIG. 3B is a cross-sectional view for describing a step subsequent to that of FIG. 3A.

FIG. 3C is a cross-sectional view for describing a step subsequent to that of FIG. 3B.

FIG. 3D is a cross-sectional view for describing a step subsequent to that of FIG. 3C.

FIG. 3E is a cross-sectional view for describing a step subsequent to that of FIG. 3D.

FIG. 3F is a cross-sectional view for describing a step subsequent to that of FIG. 3E.

FIG. 3G is a cross-sectional view for describing a step subsequent to that of FIG. 3F.

FIG. 3H is a cross-sectional view for describing a step subsequent to that of FIG. 3G.

FIG. 3I is a cross-sectional view for describing a step subsequent to that of FIG. 3H.

FIG. 4 is a flowchart showing one example of the SiC semiconductor device manufacturing method implemented with respect to a wafer structure.

FIG. 5A is a cross-sectional view which describes one example of the SiC semiconductor device manufacturing method implemented with respect to the wafer structure.

FIG. 5B is a cross-sectional view for describing a step subsequent to that of FIG. 5A.

FIG. 5C is a cross-sectional view for describing a step subsequent to that of FIG. 5B.

FIG. 5D is a cross-sectional view for describing a step subsequent to that of FIG. 5C.

FIG. 5E is a cross-sectional view for describing a step subsequent to that of FIG. 5D.

FIG. 5F is a cross-sectional view for describing a step subsequent to that of FIG. 5E.

FIG. 5G is a cross-sectional view for describing a step subsequent to that of FIG. 5F.

FIG. 5H is a cross-sectional view for describing a step subsequent to that of FIG. 5G.

FIG. 5I is a cross-sectional view for describing a step subsequent to that of FIG. 5H.

FIG. 5J is a cross-sectional view for describing a step subsequent to that of FIG. 5I.

FIG. 5K is a cross-sectional view for describing a step subsequent to that of FIG. 5J.

FIG. 5L is a cross-sectional view for describing a step subsequent to that of FIG. 5K.

FIG. 5M is a cross-sectional view for describing a step subsequent to that of FIG. 5L.

FIG. 5N is a cross-sectional view for describing a step subsequent to that of FIG. 5M.

FIG. 5O is a cross-sectional view for describing a step subsequent to that of FIG. 5N.

FIG. 5P is a cross-sectional view for describing a step subsequent to that of FIG. 5O.

FIG. 5Q is a cross-sectional view for describing a step subsequent to that of FIG. 5P.

FIG. 5R is a cross-sectional view for describing a step subsequent to that of FIG. 5Q.

FIG. 6 is a perspective view for describing a device region and an intended cutting line.

FIG. 7 is a graph for describing the formation characteristics of a modified layer according to a step of FIG. 5N.

FIG. 8 is a flowchart showing one example of an SiC semiconductor device manufacturing method according to a second preferred embodiment of the present invention.

FIG. 9 is a plan view showing an SiC semiconductor device having a functional device according to one configuration example.

FIG. 10 is a cross-sectional view along line X-X shown in FIG. 9.

FIG. 11 is a plan view showing an SiC semiconductor device having a functional device according to another configuration example.

FIG. 12 is a cross-sectional view along line XII-XII shown in FIG. 11.

FIG. 13 is a cross-sectional view showing a principal portion of the functional device.

### DESCRIPTION OF EMBODIMENTS

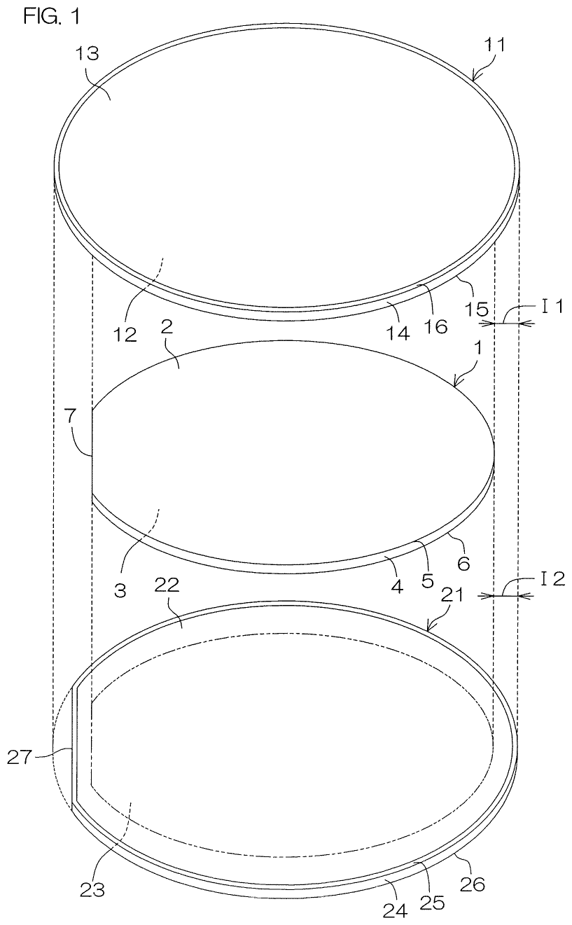

FIG. 1 is a perspective view showing an SiC wafer source 1, a first supporting member 11 and a second supporting member 21 used in an SiC (silicon carbide) semiconductor device manufacturing method according to the first preferred embodiment of the present invention. In this embodiment, the SiC wafer source 1 is constituted of an SiC monocrystal that is a hexagonal crystal. The SiC monocrystal is also one example of a monocrystal of a wide bandgap semiconductor. The wide bandgap semiconductor is a semiconductor which has a bandgap in excess of a bandgap of Si (silicon). The SiC monocrystal that is a hexagonal crystal has a plurality of polytypes including a 2H (Hexagonal)-SiC monocrystal, a 4H—SiC monocrystal, a 6H—SiC monocrystal, etc. In this embodiment, although there is shown an example in which the SiC wafer source 1 is constituted of a 4H—SiC monocrystal, this does not exclude other polytypes.

The SiC wafer source 1 is a disk-shaped or cylindrical-shaped crystal which is cut out from a hexagonal crystal SiC ingot (SiC monocrystal mass) by a slice processing method. The SiC wafer source 1 is a base member from which at least one (preferably a plurality of) SiC wafer (s) for device formation is cut out until it becomes unable to be separated. The SiC wafer source 1 may be constituted of an SiC wafer for device formation cut out from an SiC ingot. The SiC wafer source 1 may contain, across an entire area, an n-type (first conductive type) impurity or a p-type (second conductive type) impurity depending on the electrical properties of an SiC semiconductor device to be formed. That is, in the SiC semiconductor device manufacturing method, an n-type SiC wafer source 1 or a p-type SiC wafer source 1 may be used.

The SiC wafer source 1 has a first main surface 2 on one side, a second main surface 3 on the other side and a side surface 4 which connects the first main surface 2 and the second main surface 3. The first main surface 2 and the second main surface 3 are arranged along c-planes of the SiC monocrystal. The c-planes include a silicon plane ((0001) surface) and a carbon plane ((000-1) surface) of the SiC monocrystal. Preferably, the first main surface 2 is arranged along the silicon plane and the second main surface 3 is arranged along the carbon plane.

The first main surface 2 and the second main surface 3 may have an off angle which is inclined at a predetermined angle in a predetermined off direction with respect to the c-planes. The off direction is preferably an a-axis direction of the SiC monocrystal ([11-20] direction). The off angle may be in excess of 0° and not more than 10°. The off angle is preferably not more than 5°. The off angle is in particular preferably not less than 2° and not more than 4.5°. The first main surface 2 may be a ground surface, a cleavage surface, a polished surface or a mirror finished surface. The second main surface 3 may be a ground surface, a cleavage surface, a polished surface or a mirror finished surface. Surface conditions of the first main surface 2 and those of the second main surface 3 are arbitrary, and the surface conditions of the second main surface 3 are not necessarily the same as those of the first main surface 2.

The SiC wafer source 1 includes a first edge portion 5 and a second edge portion 6. The first edge portion 5 connects the first main surface 2 and the side surface 4. The first edge portion 5 is angular and not chamfered. That is, the first edge portion 5 connects the first main surface 2 and the side surface 4 at roughly a right angle. The second edge portion 6 connects the second main surface 3 and the side surface 4. The second edge portion 6 is angular and not chamfered. That is, the second edge portion 6 connects the second main surface 3 and the side surface 4 at roughly a right angle.

The SiC wafer source 1 has a first orientation flat 7 as an example of a mark indicating a crystal orientation of the SiC monocrystal on the side surface 4. The first orientation flat 7 is constituted of a notch portion that extends linearly. In this embodiment, the first orientation flat 7 extends in the a-axis direction of the SiC monocrystal. The first orientation flat 7 is not necessarily required to extend in the a-axis direction but may extend in an m-axis direction. As a matter of course, the SiC wafer source 1 may have the first orientation flat 7 extending in the a-axis direction and the first orientation flat 7 extending in the m-axis direction.

The SiC wafer source 1 may have a diameter which is not less than 25 mm and not more than 300 mm (that is, not less than 1 inch and not more than 12 inches). The diameter of the SiC wafer source 1 refers to a chord which passes through the center of the SiC wafer source 1 outside the first orientation flat 7. The SiC wafer source 1 may have a thickness of not less than 0.1 mm and not more than 50 mm. The thickness of the SiC wafer source 1 is typically not more than 20 mm. When an SiC wafer source 1 constituted of an SiC wafer for device formation cut out from an SiC ingot is used, the thickness of the SiC wafer source 1 may be not less than 0.3 mm and not more than 15 mm (preferably not more than 10 mm). In this case, the diameter of the SiC wafer source 1 may be not less than 2 inches and not more than 12 inches.

A first supporting member 11 is constituted of a plate-shaped member that supports the SiC wafer source 1 from the first main surface 2 side. As long as the SiC wafer source 1 is supported from the first main surface 2 side, any type of member can be used as the first supporting member 11. The first supporting member 11 may be constituted of a material different from that of the SiC wafer. The first supporting member 11 may be constituted of an inorganic plate, an organic plate, a metal plate, a crystal plate or an amorphous plate that is processed in a disk shape or a cylindrical shape. The first supporting member 11 is preferably constituted of a light transmissive or a transparent material. In this embodiment, the first supporting member 11 is constituted of an amorphous plate. The first supporting member 11 is preferably constituted of glass (silicon oxide).

The first supporting member 11 has a first plate surface 12 on one side (SiC wafer source 1 side), a second plate surface 13 on the other side and a plate side surface 14 which connects the first plate surface 12 and the second plate surface 13. The first plate surface 12 may be a ground surface, a cleavage surface, a polished surface or a mirror finished surface. The second plate surface 13 may be a ground surface, a cleavage surface, a polished surface or a mirror finished surface. Surface conditions of the first plate surface 12 and those of the second plate surface 13 are arbitrary, and the surface conditions of the second plate surface 13 are not necessarily the same as those of the first plate surface 12.

The first supporting member 11 includes a first plate edge portion 15 and a second plate edge portion 16. The first plate edge portion 15 connects the first plate surface 12 and the plate side surface 14. The first plate edge portion 15 is obliquely inclined from the first plate surface 12 toward the plate side surface 14 by chamfering. The first plate edge portion 15 may be R chamfered or C chamfered. The second plate edge portion 16 connects the second plate surface 13 and the plate side surface 14. The second plate edge portion 16 is obliquely inclined from the second plate surface 13 toward the plate side surface 14 by chamfering. The second plate edge portion 16 may be R chamfered or C chamfered.

The presence or absence of a chamfered portion in the first plate edge portion 15 and the presence or absence of a chamfered portion in the second plate edge portion 16 are arbitrary. One or both of the first plate edge portion 15 and the second plate edge portion 16 may be free of a chamfered portion and angular. However, in view of handling, it is preferable that both the first plate edge portion 15 and the second plate edge portion 16 have a chamfered portion. In this description, a word of “handling” includes not only carrying-in/carrying-out regarding equipment for manufacturing the SiC semiconductor device but also distribution in a market.

The diameter and the thickness of the first supporting member 11 are arbitrary. However, in view of handling of the SiC wafer source 1, the first supporting member 11 preferably has a diameter equal to or larger than the diameter of the SiC wafer source 1. Further, the first supporting member 11 preferably has a thickness equal to or thicker than the thickness of the SiC wafer source 1. In this embodiment, the first supporting member 11 has a diameter in excess of the diameter of the SiC wafer source 1. A first interval I1 between a peripheral edge of the SiC wafer source 1 and a peripheral edge of the first supporting member 11 when a central portion of the SiC wafer source 1 overlaps a central portion of the first supporting member 11 is preferably not less than 0 mm and not more than 10 mm.

A second supporting member 21 is a plate-shaped member that supports the SiC wafer source 1 from the second main surface 3 side. The second supporting member 21 is preferably constituted of a light transmissive or transparent material which suppresses attenuation of laser light. A melting point of the second supporting member 21 is preferably equal to or higher than a melting point of the SiC wafer source 1. A ratio of a thermal expansion coefficient of the second supporting member 21 in relation to a thermal expansion coefficient of the SiC wafer source 1 is preferably not less than 0.5 and not more than 1.5. In particular preferably, the second supporting member 21 is constituted of the same material as the SiC wafer source 1 (that is, SiC). In this case, the second supporting member 21 may be constituted of an SiC monocrystal or an SiC polycrystal.

When the second supporting member 21 is constituted of an SiC monocrystal, the second supporting member 21 is preferably constituted of the SiC monocrystal that is a hexagonal crystal. In this embodiment, there is shown an example in which the second supporting member 21 is constituted of a 4H—SiC monocrystal SiC wafer, which shall not, however, exclude other polytypes. In this embodiment, the second supporting member 21 is constituted of a crystal (that is, an SiC wafer) in a disk shape or a cylindrical shape which is cut out from a hexagonal crystal SiC ingot (an SiC monocrystal mass) by a slice processing method.

An impurity concentration of the second supporting member 21 is set independently from an SiC semiconductor device which is to be formed in the SiC wafer source 1. The impurity concentration of the second supporting member 21 is preferably different from the impurity concentration of the SiC wafer source 1. The impurity concentration of the second supporting member 21 is preferably less than the impurity concentration of the SiC wafer source 1. In particular preferably, the second supporting member 21 is not doped with an impurity. In this case, absorption (attenuation) of laser light resulting from the second supporting member 21 is suppressed.

The second supporting member 21 may contain vanadium as an impurity. When the second supporting member 21 contains an n-type impurity or a p-type impurity, the impurity concentration of the second supporting member 21 is preferably not more than 1×10¹⁸ cm⁻³. It is noted that laser light having a wavelength of not more than 390 μm tends to undergo absorption (attenuation) by an SiC monocrystal, irrespective of whether an impurity is added or not.

The second supporting member 21 has a first plate surface 22 on one side (SiC wafer source 1 side), a second plate surface 23 on the other side and a plate side surface 24 which connects the first plate surface 22 and the second plate surface 23. The first plate surface 22 and the second plate surface 23 are arranged along the c-planes of the SiC monocrystal. Preferably, the first plate surface 22 is arranged along the silicon plane and the second plate surface 23 is arranged along the carbon plane.

The first plate surface 22 and the second plate surface 23 may have an off angle which is inclined at a predetermined angle in a predetermined off direction with respect to the c-planes. The off direction is preferably an a-axis direction of the SiC monocrystal ([11-20] direction). The off angle may be in excess of 0° and not more than 10°. The off angle is preferably not more than 5°. The off angle is in particular preferably not less than 2° and not more than 4.5°. Preferably, the off angle of the second supporting member 21 is substantially equal to the off angle of the SiC wafer source 1. The off angle of the second supporting member 21 preferably has a value within ±10% on the basis of a value of the off angle of the SiC wafer source 1.

The first plate surface 22 may be a ground surface, a cleavage surface, a polished surface or a mirror finished surface. The second plate surface 23 may be a ground surface, a cleavage surface, a polished surface or a mirror finished surface. Surface conditions of the first plate surface 22 and those of the second plate surface 23 are arbitrary, and the surface conditions of the second plate surface 23 are not necessarily the same as those of the first plate surface 22.

The second supporting member 21 includes a first plate edge portion 25 and a second plate edge portion 26. The first plate edge portion 25 connects the first plate surface 22 and the plate side surface 24. The first plate edge portion 25 is obliquely inclined from the first plate surface 22 toward the plate side surface 24 by chamfering. The first plate edge portion 25 may be R chamfered or C chamfered. The second plate edge portion 26 connects the second plate surface 23 and the plate side surface 24. The second plate edge portion 26 is obliquely inclined from the second plate surface 23 toward the plate side surface 24 by chamfering. The second plate edge portion 26 may be R chamfered or C chamfered.

The presence or absence of a chamfered portion in the first plate edge portion 25 and the presence or absence of a chamfered portion in the second plate edge portion 26 are arbitrary. One or both of the first plate edge portion 25 and the second plate edge portion 26 may be free of a chamfered portion and angular. However, in view of handling, it is preferable that both the first plate edge portion 25 and the second plate edge portion 26 have a chamfered portion.

The second supporting member 21 has a second orientation flat 27 as an example of a mark indicating the crystal orientation of the SiC monocrystal in the plate side surface 24. Preferably, the second orientation flat 27 indirectly indicates the crystal orientation of the SiC wafer source 1. The second orientation flat 27 is constituted of a notch portion that extends linearly. In this embodiment, the second orientation flat 27 extends in the a-axis direction of the SiC monocrystal. The second orientation flat 27 is not necessarily required to extend in the a-axis direction but may extend in the m-axis direction. As a matter of course, the second supporting member 21 may have the second orientation flat 27 extending in the a-axis direction and the second orientation flat 27 extending in the m-axis direction.

The diameter and the thickness of the second supporting member 21 are arbitrary. The diameter of the second supporting member 21 refers to a chord which passes through the center of the second supporting member 21 outside the second orientation flat 27. In view of handling of the SiC wafer source 1, the second supporting member 21 preferably has a diameter equal to or larger than the diameter of the SiC wafer source 1. Further, the second supporting member 21 preferably has a thickness equal to or thicker than the thickness of the SiC wafer source 1. In this embodiment, the second supporting member 21 has a diameter in excess of the diameter of the SiC wafer source 1. A second interval 12 between a peripheral edge of the SiC wafer source 1 and a peripheral edge of the second supporting member 21 when a central portion of the SiC wafer source 1 overlaps a central portion of the second supporting member 21 is preferably not less than 0 mm and not more than 10 mm.

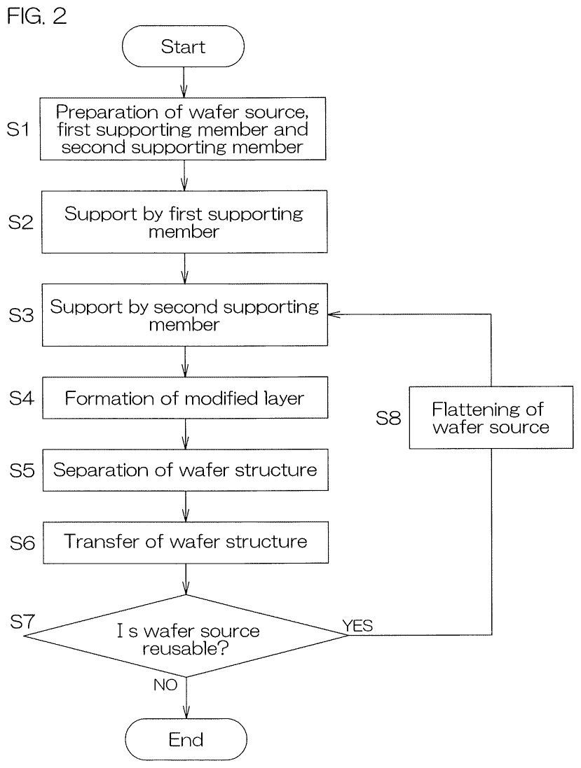

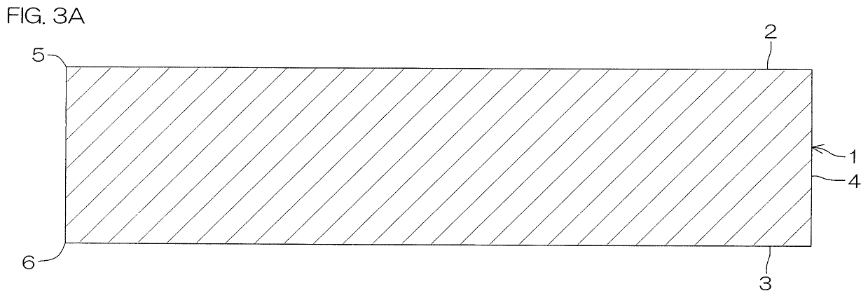

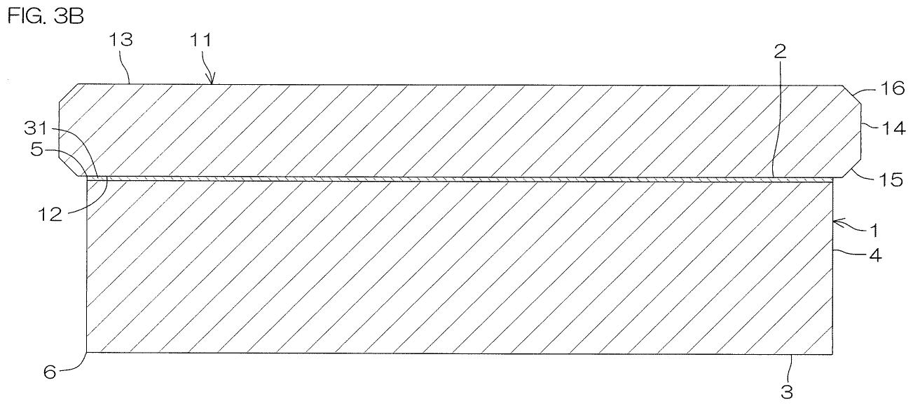

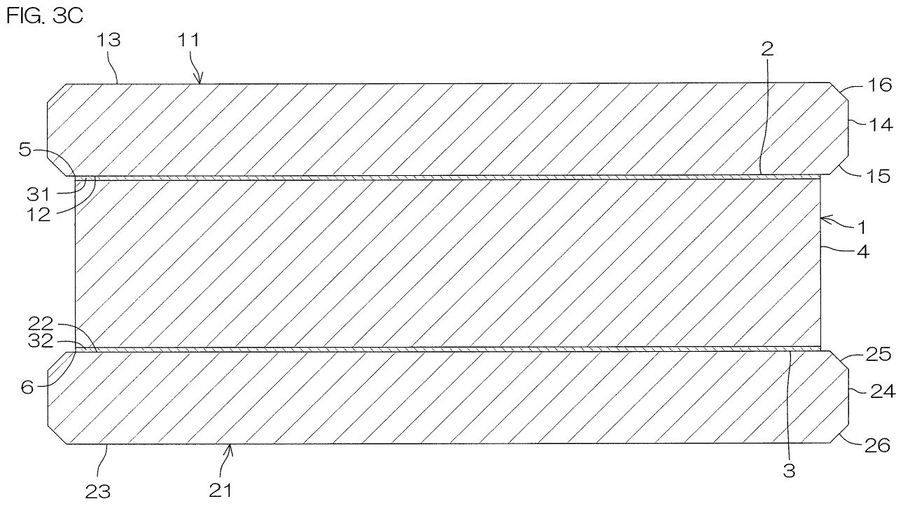

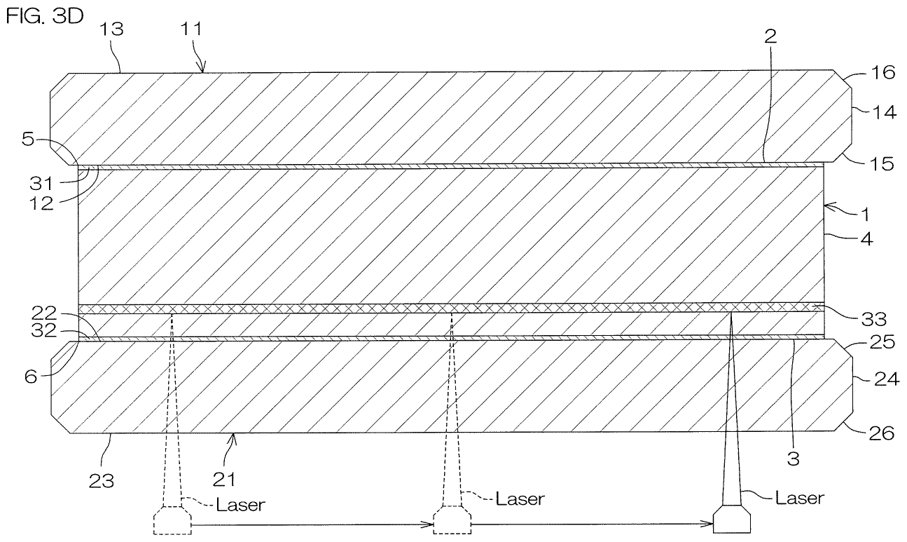

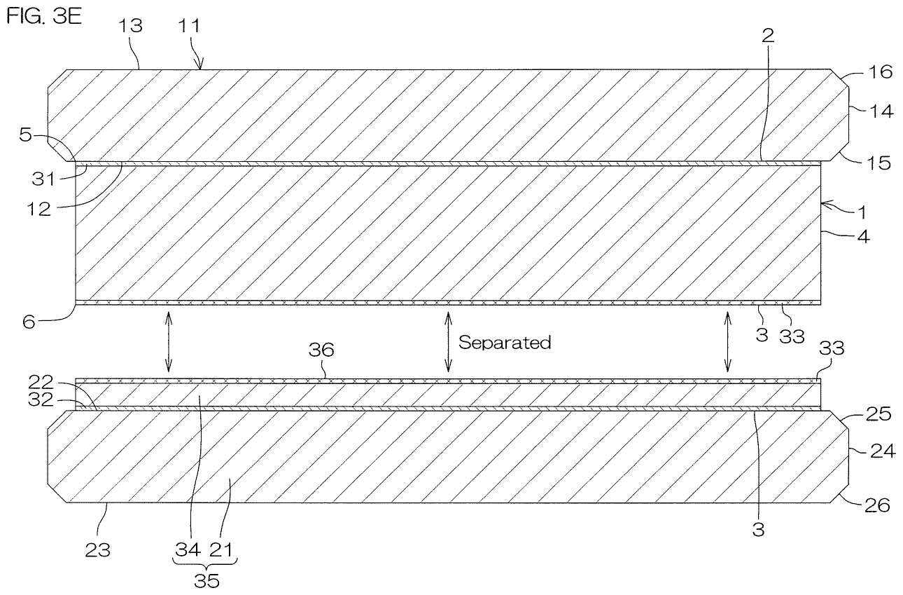

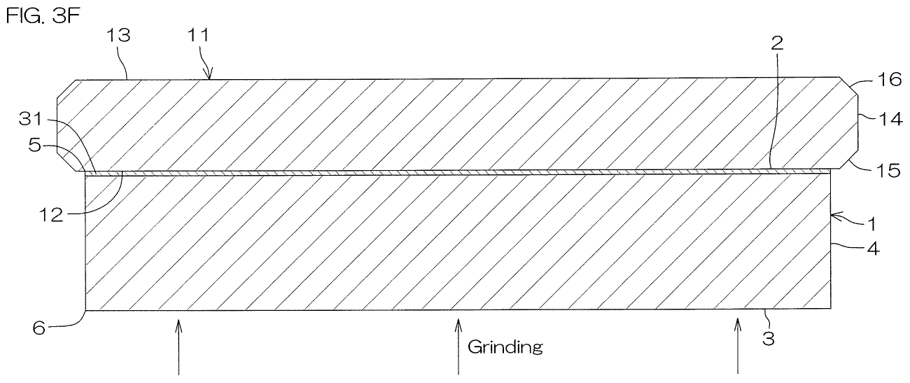

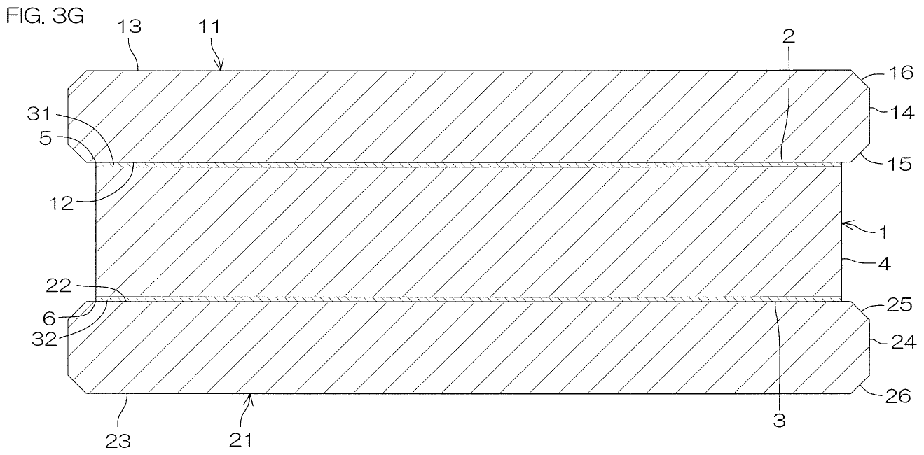

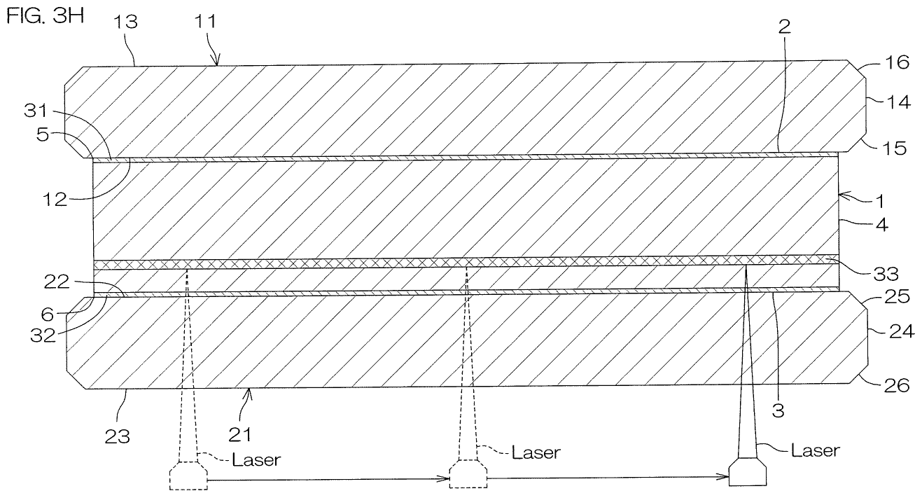

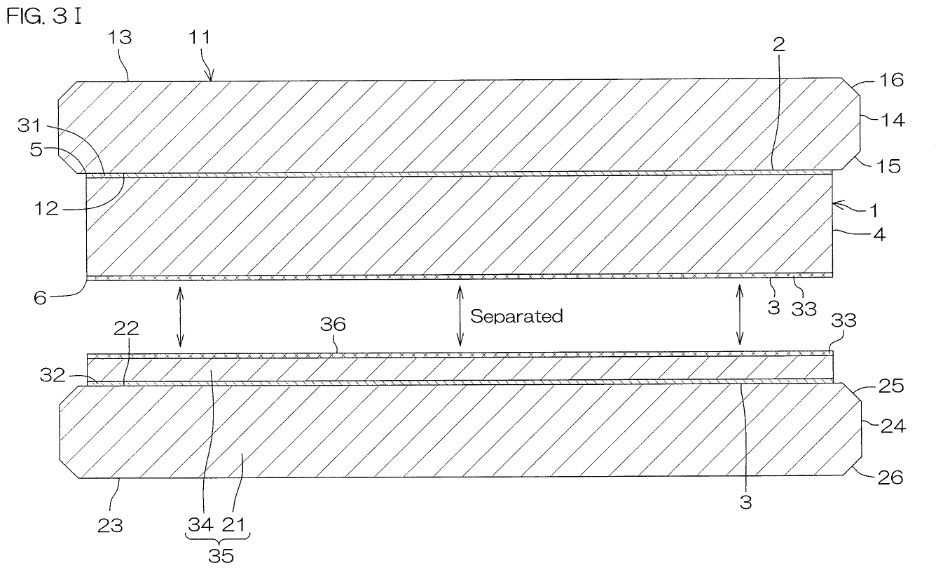

FIG. 2 is a flowchart showing an example of the SiC semiconductor device manufacturing method. FIG. 3A to FIG. 31 are each a cross-sectional view for describing an example of the SiC semiconductor device manufacturing method. In FIG. 3A to FIG. 3I, for the sake of convenience, the SiC wafer source 1, the first supporting member 11 and the second supporting member 21 are shown in a simplified form. First, with reference to FIG. 3A, in manufacturing the SiC semiconductor device, the SiC wafer source 1, the first supporting member 11 and the second supporting member 21 are prepared (Step S1 in FIG. 2). In FIG. 3A, only the SiC wafer source 1 is shown.

Next, with reference to FIG. 3B, the SiC wafer source 1 is supported by the first supporting member 11 from the first main surface 2 side (silicon plane side) (Step S2 in FIG. 2). The first plate surface 12 of the first supporting member 11 may be directly bonded to the first main surface 2 of the SiC wafer source 1 by a room temperature bonding method which is one example of a direct bonding method. In the room temperature bonding method, an activating step and a bonding step are implemented. In the activating step, for example, the first main surface 2 of the SiC wafer source 1 and the first plate surface 12 of the first supporting member 11 are irradiated with atoms and ions under high vacuum, and the first main surface 2 and the first plate surface 12 are each activated by dangling bonds.

In the bonding step, the activated first main surface 2 and the activated first plate surface 12 are bonded. A first amorphous bonding layer 31 (Si/SiC amorphous bonding layer) which contains at least Si (silicon) is formed between the first main surface 2 and the first plate surface 12 after the bonding. The SiC wafer source 1 and the first supporting member 11 are bonded by the first amorphous bonding layer 31. The room temperature bonding method may include a heat treatment step and a pressurization step for enhancing the bonding strength of the SiC wafer source 1 and the first supporting member 11.

Regarding this step, a description has been given of an example in which the first supporting member 11 is bonded to the SiC wafer source 1 by a direct bonding method. However, as long as the SiC wafer source 1 can be supported by the first supporting member 11, the bonding method of the first supporting member 11 to the SiC wafer source 1 is arbitrary. For example, the first supporting member 11 may be bonded to the SiC wafer source 1 by an adhesive agent. In this case, an adhesive layer constituted of the adhesive agent is formed between the SiC wafer source 1 and the first supporting member 11.

Next, with reference to FIG. 3C, the SiC wafer source 1 is supported by the second supporting member 21 from the second main surface 3 side (carbon plane side) (Step S3 in FIG. 2). In this step, the second supporting member 21 supports the SiC wafer source 1 such that the second orientation flat 27 will extend in parallel to the first orientation flat 7 at a position close to the first orientation flat 7. In a state that the SiC wafer source 1 is held between the first supporting member 11 and the second supporting member 21, the crystal orientation of the SiC wafer source 1 is determined by both of the first orientation flat 7 and the second orientation flat 27.

In this step, the first plate surface 22 (silicon plane) of the second supporting member 21 is bonded to the second main surface 3 (carbon plane) of the SiC wafer source 1 by a room temperature bonding method which is an example of a direct bonding method. In the room temperature bonding method, an activating step and a bonding step are implemented. In the activating step, for example, the second main surface 3 of the SiC wafer source 1 and the first plate surface 22 of the second supporting member 21 are irradiated with atoms and ions under high vacuum, and the second main surface 3 and the first plate surface 22 are each activated by dangling bonds.

In the bonding step, the activated second main surface 3 and the activated first plate surface 22 are bonded. A second amorphous bonding layer 32 (SiC amorphous bonding layer) which contains at least C (carbon) is formed between the second main surface 3 and the first plate surface 22 after the bonding. The SiC wafer source 1 and the second supporting member 21 are bonded by the second amorphous bonding layer 32. The room temperature bonding method may include a heat treatment step and a pressurization step for enhancing the bonding strength of the SiC wafer source 1 and the second supporting member 21.

The second amorphous bonding layer 32 has a light absorption coefficient larger than a light absorption coefficient of the SiC wafer source 1. The light absorption coefficient of the second amorphous bonding layer 32 is larger than the light absorption coefficient of the second supporting member 21. A thickness of the second amorphous bonding layer 32 may be in excess of 0 μm and not more than 5 μm. The thickness of the second amorphous bonding layer 32 is preferably not more than 1 μm.

Next, with reference to FIG. 3D, a modified layer 33 along a horizontal direction parallel to the first main surface 2 is formed in a thickness direction intermediate portion of the SiC wafer source 1 (Step S4 in FIG. 2). A distance between the first plate surface 22 of the second supporting member 21 and the modified layer 33 is set depending on the thickness of a wafer to be obtained from the SiC wafer source 1. The distance between the first plate surface 22 of the second supporting member 21 and the modified layer 33 may be not less than 5 μm and not more than 300 μm. The distance between the first plate surface 22 of the second supporting member 21 and the modified layer 33 is typically not less than 5 μm and not more than 250 μm.

In this step, a light condensing portion is set at the thickness direction intermediate portion of the SiC wafer source 1, and the SiC wafer source 1 is irradiated with laser light from a laser light irradiation unit via the second supporting member 21. A position of the SiC wafer source 1 irradiated with laser light is moved along the horizontal direction. Thereby, the modified layer 33 in which a crystalline structure of the SiC monocrystal is partially modified to other properties is formed at a portion of the SiC wafer source 1 irradiated with laser light. That is, the modified layer 33 is a laser processing mark formed by irradiation of laser light. The modified layer 33 is constituted of a layer in which a density, a refractive index, a mechanical strength (crystalline strength) or other physical characteristics are modified to properties different from that of the SiC wafer source 1 to give physical properties more fragile than that of the SiC monocrystal.

The modified layer 33 may include at least one layer among an amorphous layer, a melt re-hardened layer, a defect layer, a dielectric breakdown layer and a refractive index change layer. The amorphous layer is a layer in which a portion of the SiC wafer source 1 is made amorphous. The melt re-hardened layer is a layer in which a portion of the SiC wafer source 1 is hardened after being melted. The defect layer is a layer which includes a hole, a crack, etc., formed in the SiC wafer source 1. The dielectric breakdown layer is a layer in which a portion of the SiC wafer source 1 has undergone dielectric breakdown. The refractive index change layer is a layer in which a portion of the SiC wafer source 1 has changed to a refractive index different from the SiC wafer source 1.

Next, with reference to FIG. 3E, the SiC wafer source 1 is cut along a horizontal direction from a thickness direction intermediate portion with the modified layer 33 as a starting point (Step S5 in FIG. 2). In this step, an external force is applied to the SiC wafer source 1 in a state of being held between the first supporting member 11 and the second supporting member 21, and the SiC wafer source 1 is cleaved in the horizontal direction with the modified layer 33 as a starting point. The external force applied to the SiC wafer source 1 may be ultrasonic waves.

Thereby, an SiC wafer structure 35 which includes the second supporting member 21 and an SiC wafer 34 is separated from the SiC wafer source 1. The SiC wafer structure 35 is interposed between the second supporting member 21 and the SiC wafer 34 and includes the second amorphous bonding layer 32 which bonds the second supporting member 21 and the SiC wafer 34. In this embodiment, the second amorphous bonding layer 32 is formed as a starting point of separating the second supporting member 21 and the SiC wafer 34 (specifically, a cleavage starting point) in a subsequent step.

The SiC wafer 34 is cut away from the SiC wafer source 1 as a wafer for device formation. A section plane of the SiC wafer 34 is arranged along the silicon plane. The SiC wafer 34 is separated from the SiC wafer source 1 such that the first orientation flat 7 is taken over from the SiC wafer source 1. Therefore, the SiC wafer 34 also has the first orientation flat 7. After being separated from the SiC wafer source 1, the SiC wafer structure 35 is transferred to a different place (Step S6 in FIG. 2). That is, the second supporting member 21 and the SiC wafer 34 are handled in an integrated manner as the SiC wafer structure 35. The section plane of the SiC wafer source 1 (cleavage surface) becomes the second main surface 3.

Next, a judgment is made on whether the SiC wafer source 1 is reusable or not (Step S7 in FIG. 2). When the SiC wafer source 1 has such a thickness and a condition that another SiC wafer 34 can be obtained, the SiC wafer source 1 may be judged to be reusable. When the SiC wafer source 1 is not reusable (Step S7 in FIG. 2: NO), the steps of the SiC wafer source 1 are ended.

When the SiC wafer source 1 is not reusable (Step S7 in FIG. 2: NO), the first supporting member 11 may be removed from the SiC wafer source 1 and reused as the first supporting member 11 for supporting another SiC wafer source 1. When the first supporting member 11 is reused, the first plate surface 12 is preferably flattened (smoothed) by a grinding method and/or an etching method. The SiC wafer source 1 and/or the first amorphous bonding layer 31 which remain in the first plate surface 12 of the first supporting member 11 may be removed by a grinding method and/or an etching method. A grinding step (polishing step) of the first plate surface 12 may be implemented by a CMP (Chemical Mechanical Polishing) method.

With reference to FIG. 3F, when the SiC wafer source 1 is reusable (Step S7 in FIG. 2: YES), a reusing step of the SiC wafer source 1 is implemented. In the reusing step of the SiC wafer source 1, in a state of being supported by the first supporting member 11, the second main surface 3 (cleavage surface) of the SiC wafer source 1 is flattened (smoothed) by a grinding method and/or an etching method (Step S8 in FIG. 2).

The second main surface 3 may be polished by a CMP method. The grinding step may include a polishing step or a mirror finishing step of the second main surface 3.

Preferably, the second edge portion 6 of the SiC wafer source 1 is not chamfered. That is, the second edge portion 6 of the SiC wafer source 1 is preferably kept angular even after the SiC wafer structure 35 has been obtained.

Next, with reference to FIG. 3G, via the step similar to that of FIG. 3C, the SiC wafer source 1 is supported by the second supporting member 21 from the second main surface 3 side (Step S3 in FIG. 2). Next, with reference to FIG. 3H, via the step similar to that of FIG. 3D, the modified layer 33 along the horizontal direction parallel to the first main surface 2 is formed in a thickness direction intermediate portion of the SiC wafer source 1 (Step S4 in FIG. 2). Next, with reference to FIG. 3I, via the step similar to that of FIG. 3E, the SiC wafer source 1 is cut along the horizontal direction from the thickness direction intermediate portion with the modified layer 33 as a starting point, and the SiC wafer structure 35 which includes the second supporting member 21 and the SiC wafer 34 is cut away from the SiC wafer source 1 (Step S5 in FIG. 2).

The SiC wafer structure 35 cut away from the SiC wafer source 1 is transferred to a different place in a state that the second supporting member 21 and the SiC wafer 34 are made in an integrated state (Step S6 in FIG. 2). Thereafter, a judgment is made again on whether the SiC wafer source 1 is reusable or not (Step S7 in FIG. 2). As described so far, in the SiC semiconductor device manufacturing method, the reusing step of the SiC wafer source 1 is implemented repeatedly until the SiC wafer source 1 becomes unable to be separated.

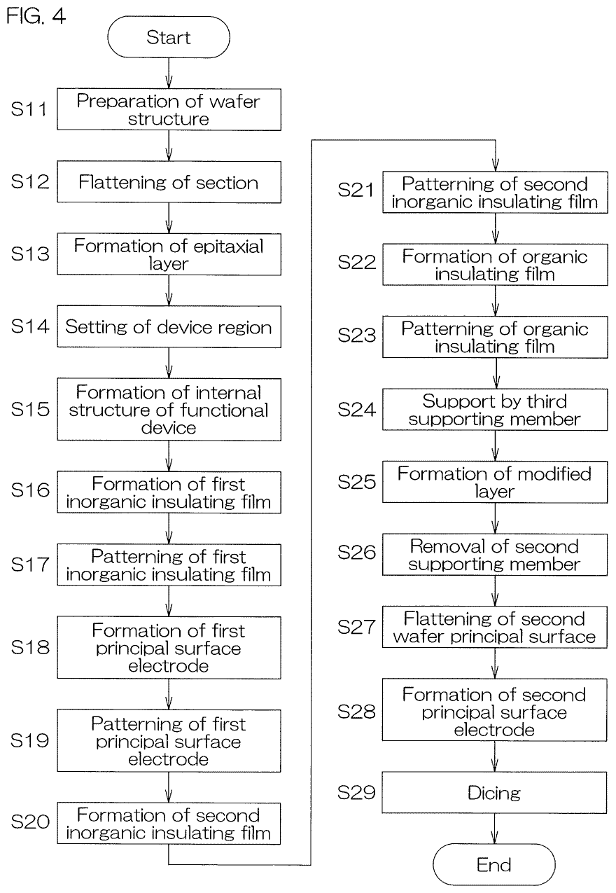

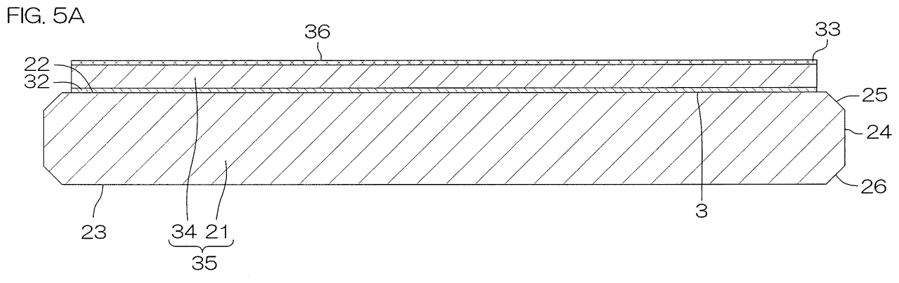

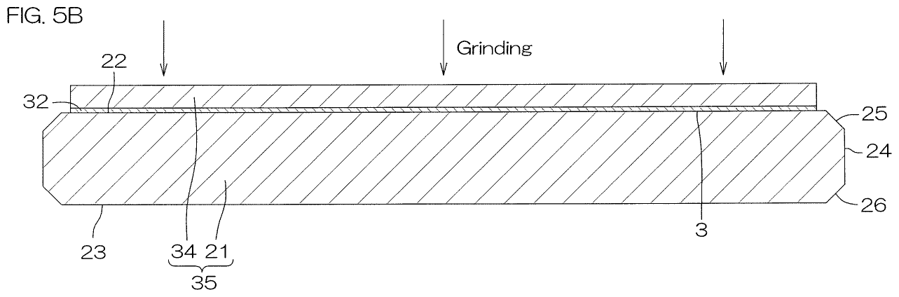

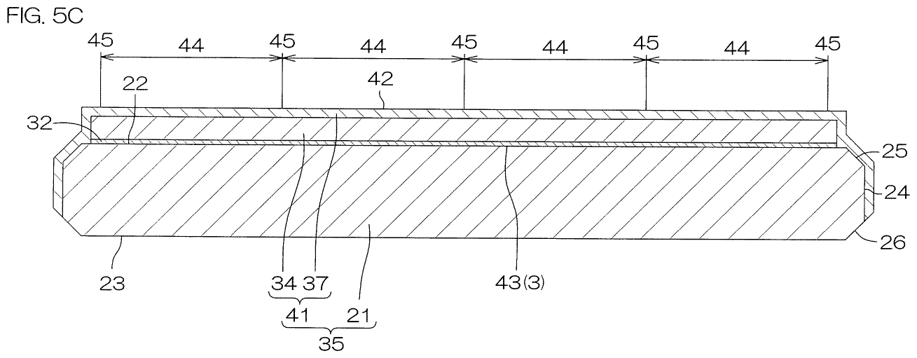

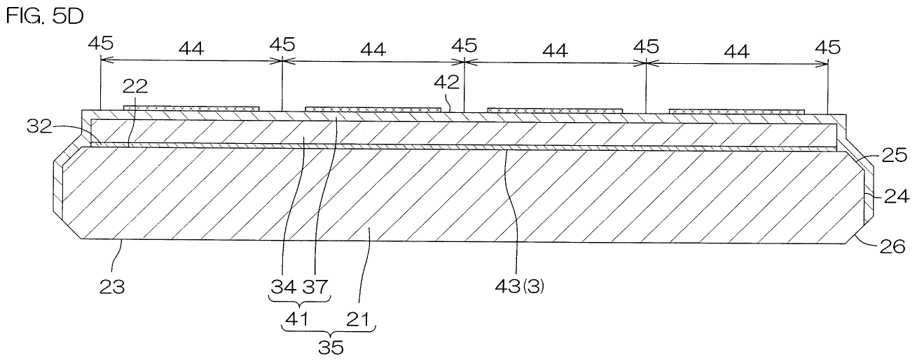

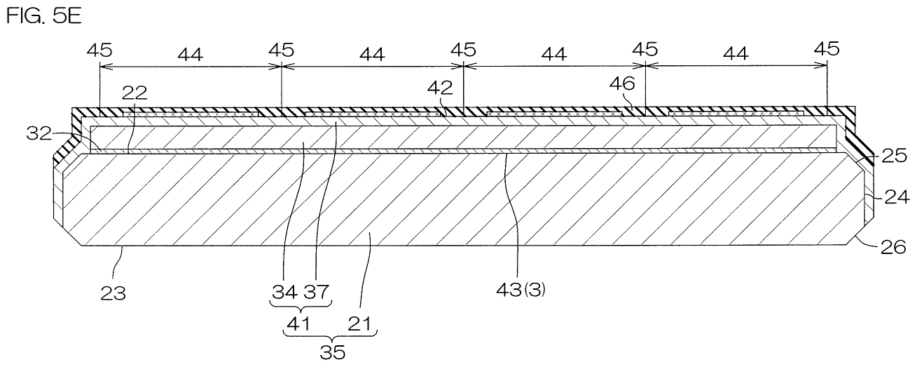

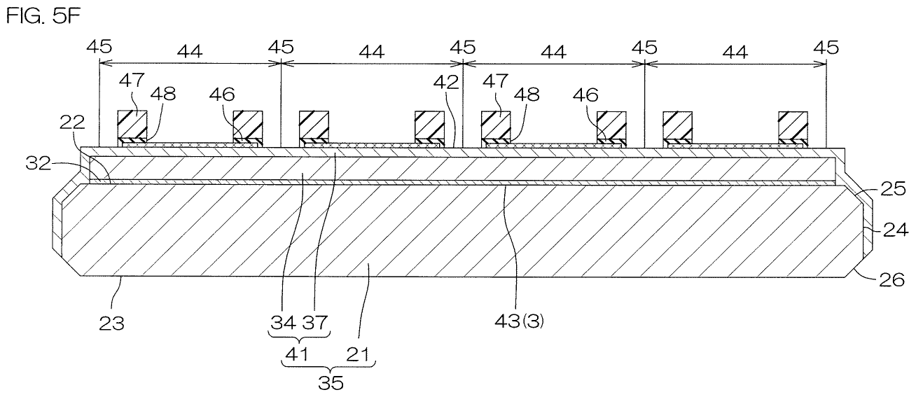

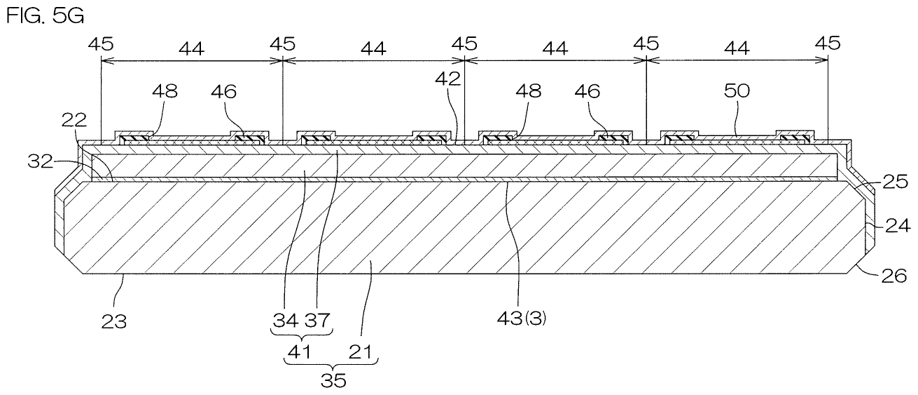

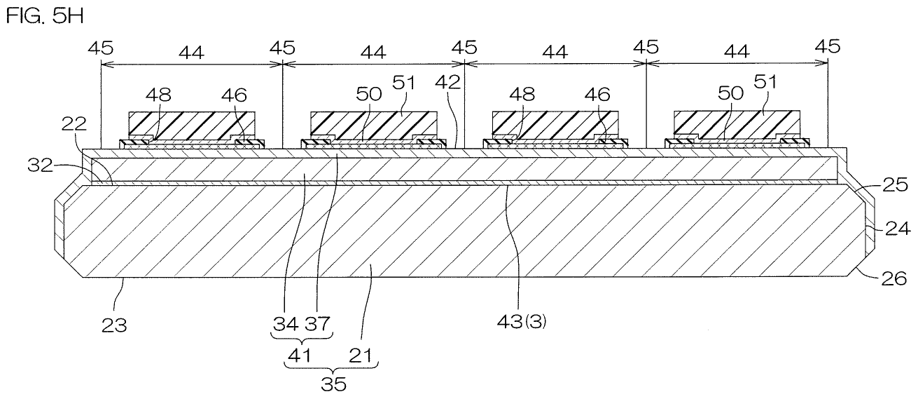

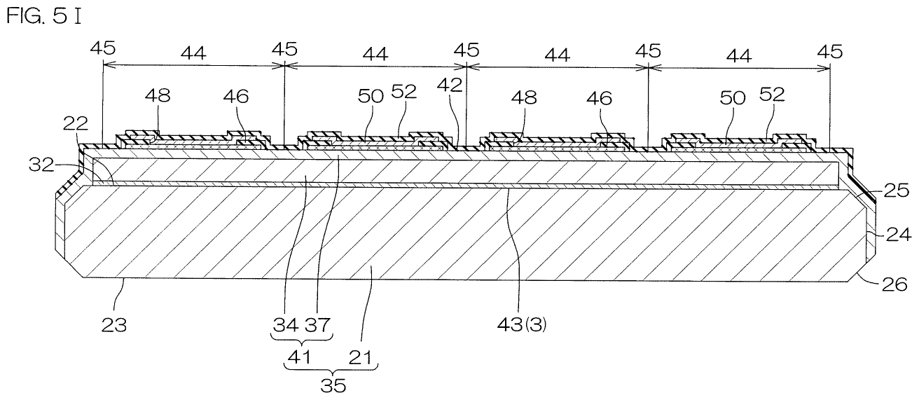

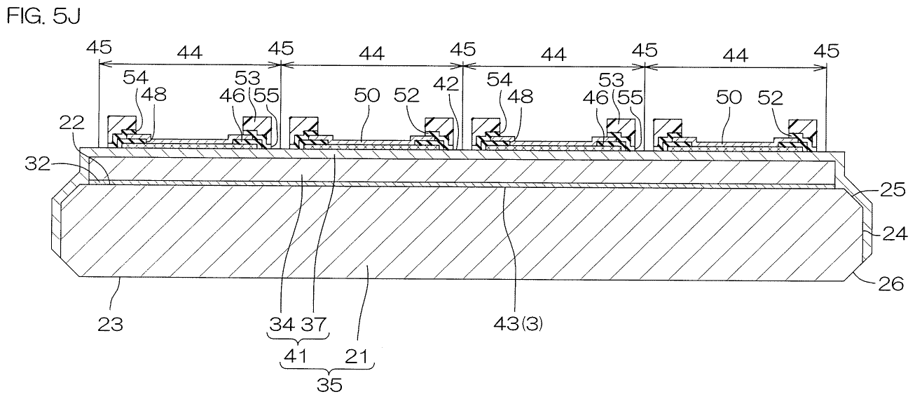

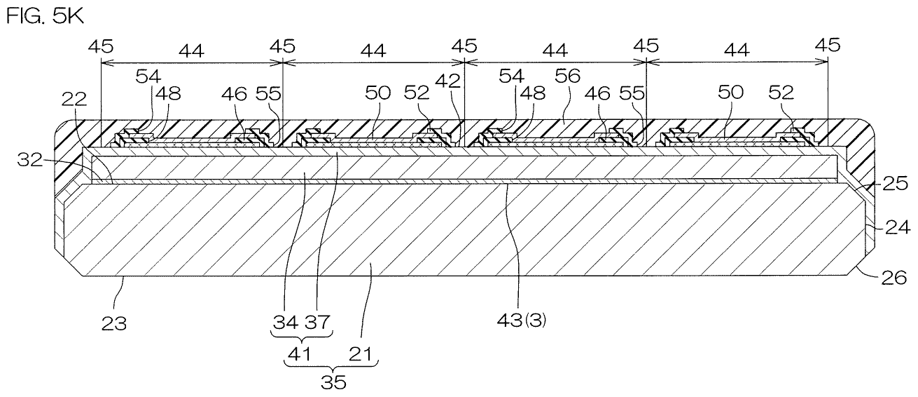

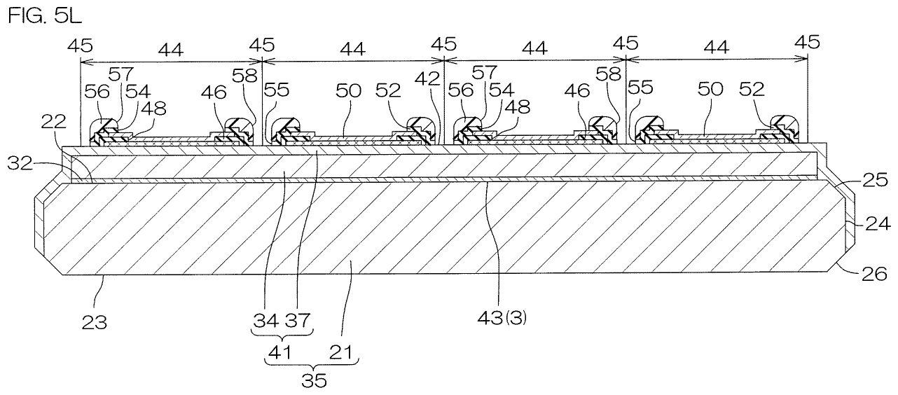

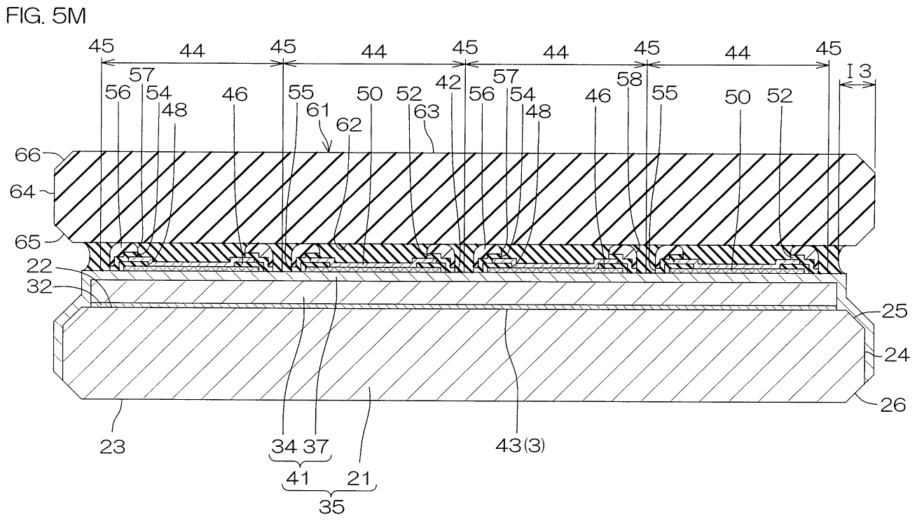

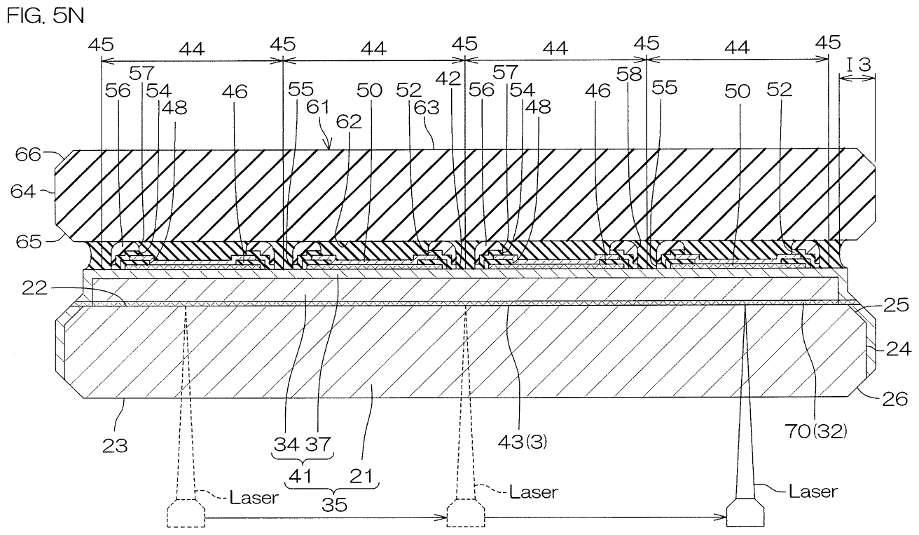

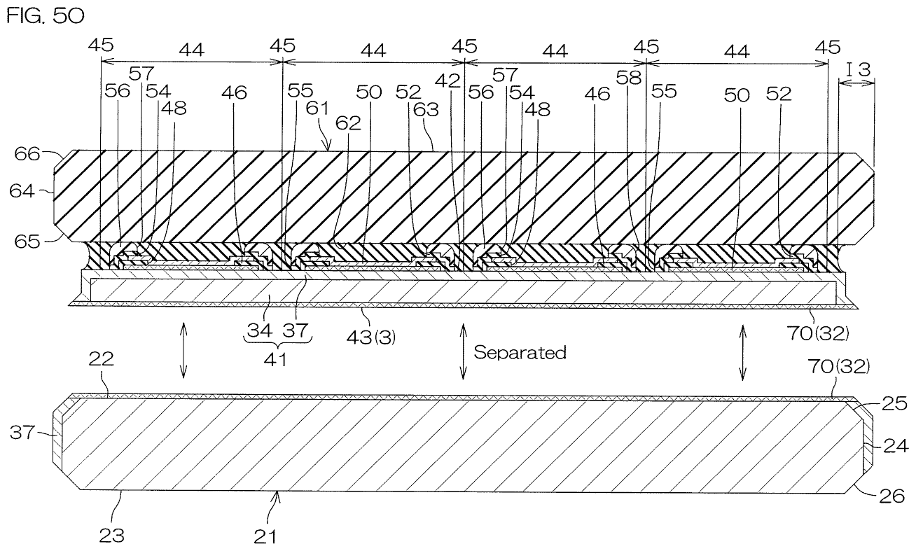

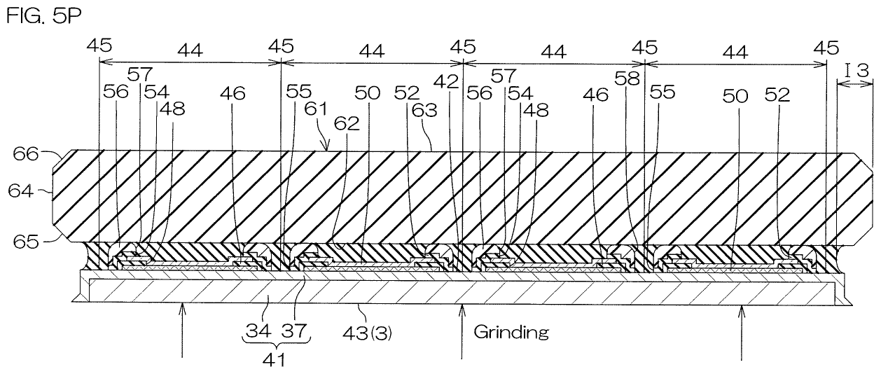

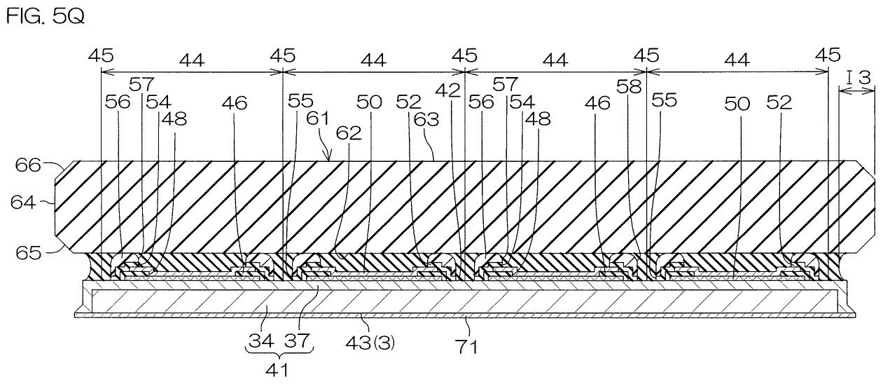

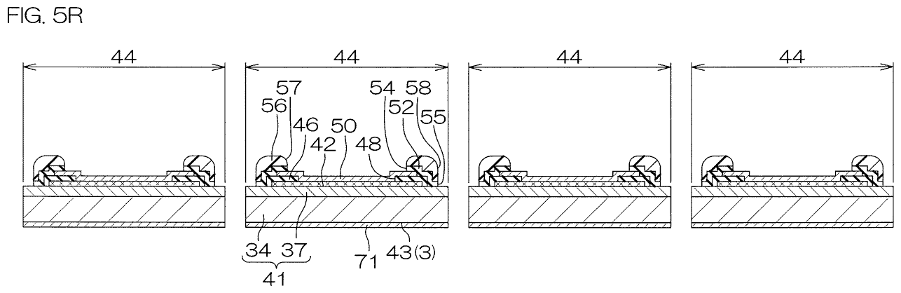

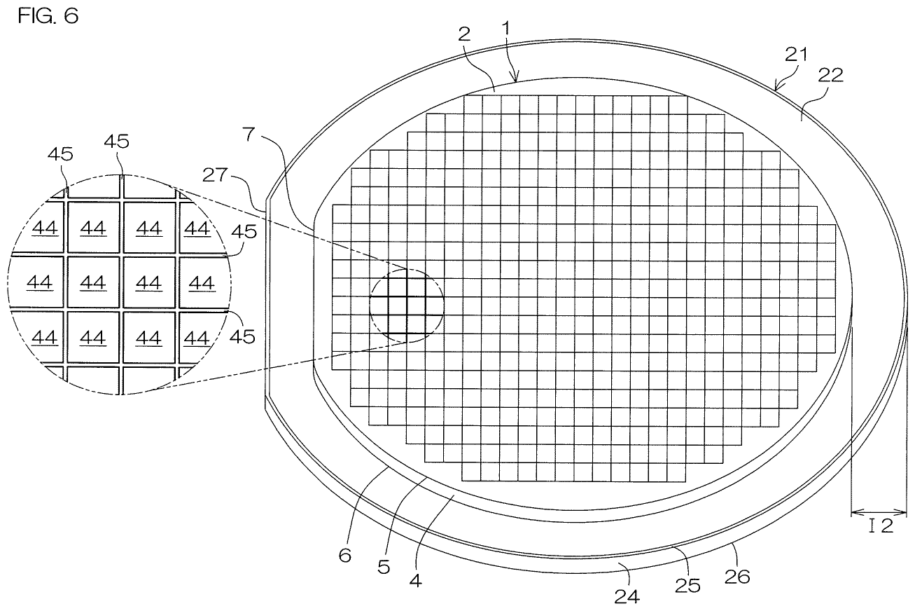

FIG. 4 is a flowchart showing one example of the SiC semiconductor device manufacturing method which is implemented with respect to the SiC wafer structure 35. FIG. 5A to FIG. 5R are each a cross-sectional view for describing one example of the SiC semiconductor device manufacturing method implemented with respect to the SiC wafer structure 35. FIG. 6 is a perspective view for describing a device region 44 and an intended cutting line 45 set in the SiC wafer structure 35.

In the SiC semiconductor device manufacturing method, after the transferring step of the SiC wafer structure 35 (Step S6 in FIG. 2), a step of forming a functional device in the SiC wafer 34 (Steps S11 to S23 in FIG. 4) and a step of making the SiC wafer 34 into individual pieces (Steps S24 to S29 in FIG. 4) are implemented. When the plurality of SiC wafers 34 (SiC wafer structures 35) are cut out from a singular SiC wafer source 1, a type of the functional device formed in the plurality of SiC wafers 34 are arbitrary. That is, a first SiC wafer 34 may be used to manufacture a first SiC semiconductor device having a first functional device, and a second SiC wafer 34 may be used to manufacture a second SiC semiconductor device having a second functional device similar in type to or different in type from the first functional device.

The functional device may include at least one of a semiconductor switching device, a semiconductor rectifying device and a passive device. The semiconductor switching device may include at least one of a MISFET (Metal Insulator Semiconductor Field Effect Transistor), a BJT (Bipolar Junction Transistor), an IGBT (Insulated Gate Bipolar Junction Transistor) and a JFET (Junction Field Effect Transistor).

The semiconductor rectifying device may include at least one of a pn bonding diode, a pin bonding diode, a Zener Diode, a SBD (Schottky Barrier Diode) and an FRD (Fast Recovery Diode). The passive device may include at least one of a resistor, a capacitor, an inductor and a fuse. The functional device may include a circuit network in which at least two of the semiconductor switching device, the semiconductor rectifying device and the passive device are combined.

The circuit network may be an integrated circuit such as an LSI (Large Scale Integration), an SSI (Small Scale Integration), an MSI (Medium Scale Integration), a VLSI (Very Large Scale Integration), a ULSI (Ultra-Very Large Scale Integration), etc. The functional device formed into the SiC wafer 34 is typically one or both of a MISFET and an SBD.

First, with reference to FIG. 5A, in manufacturing the SiC semiconductor device, the SiC wafer structure 35 is prepared (Step S11 in FIG. 4). Next, with reference to FIG. 5B, in a state of being supported by the second supporting member 21, a section plane 36 of the SiC wafer 34 (cleavage surface) is flattened (smoothed) by a grinding method and/or an etching method (Step S12 in FIG. 4). The section plane 36 may be polished by a CMP method. The grinding step may include a polishing step or a mirror finishing step of the section plane 36. Preferably, an edge portion of the SiC wafer 34 is not chamfered. That is, the edge portion of the SiC wafer 34 is preferably kept angular.

Next, with reference to FIG. 5C, an SiC epitaxial layer 37 is formed on the section plane 36 after the polishing step by an epitaxial growth method (Step S13 in FIG. 4). When the SiC wafer 34 contains an n-type impurity, the SiC epitaxial layer 37 may have an n-type impurity concentration less than an n-type impurity concentration of the SiC wafer 34. A thickness of the SiC epitaxial layer 37 may be not less than 1 μm and not more than 50 μm. The thickness of the SiC epitaxial layer 37 is preferably not less than 5 μm and not more than 20 μm. In this embodiment, the SiC epitaxial layer 37 is formed on a side surface of the SiC wafer 34 and on the second supporting member 21.

Thereby, an SiC epi-wafer 41 which includes the SiC wafer 34 and the SiC epitaxial layer 37 is formed on the second supporting member 21 in the SiC wafer structure 35. The SiC epi-wafer 41 has a first wafer main surface 42 on one side and a second wafer main surface 43 on the other side. The first wafer main surface 42 is a surface in which the functional device is formed. The second wafer main surface 43 corresponds to the second main surface 3 of the SiC wafer source 1 and is bonded to the second supporting member 21 via the second amorphous bonding layer 32.

Next, a plurality of device regions 44 and intended cutting lines 45 for demarcating the plurality of device regions 44 are set on the first wafer main surface 42 (Step S14 in FIG. 4). In FIG. 5C, the four device regions 44 are indicated and the intended cutting lines 45 are indicated by a straight line (hereinafter, the same applies to FIG. 5D to FIG. 5R). With reference to FIG. 6, the plurality of device regions 44 respectively correspond to the SiC semiconductor devices and are set in a matrix along the a-axis direction and the m-axis direction of the SiC monocrystal, for example, in a plan view. The intended cutting lines 45 are set in a lattice extending in the a-axis direction and the m-axis direction of the SiC monocrystal in accordance with the array of the plurality of device regions 44 in a plan view.

Next, with reference to FIG. 5D, an internal structure of the functional device is formed in each of the plurality of device regions 44 on the first wafer main surface 42 (Step S15 in FIG. 4). In FIG. 5D, for the sake of convenience, the internal structure of the functional device is indicated by a box to which a cross hatching is given (hereinafter, the same applies to FIG. 5E to FIG. 5R). The internal structure of the functional device includes at least one of an n-type semiconductor region, a p-type semiconductor region and a trench structure in accordance with functions of the functional device.

The n-type semiconductor region is formed by introducing an n-type impurity into the SiC epitaxial layer 37 via an ion implantation mask. The p-type semiconductor region is formed by introducing a p-type impurity into the SiC epitaxial layer 37 via an ion implantation mask. The trench structure includes a trench which is formed in the first wafer main surface 42, an insulating film which covers an inner wall of the trench and an electrode which is embedded in the trench across the insulating film.

The trench is formed in the first wafer main surface 42 by an etching method via a mask. The insulating film is formed by at least one of a thermal oxidation treatment method and a CVD (Chemical Vapor Deposition) method. The insulating film may cover not only the inner wall of the trench but also an entire area of the first wafer main surface 42 as a main surface insulating film. The electrode is formed, for example, by depositing polysilicon by a CVD method and then removing an unnecessary portion of the polysilicon by an etch back method.

Next, with reference to FIG. 5E, a first inorganic insulating film 46 is formed on the first wafer main surface 42 (Step S16 in FIG. 4). The first inorganic insulating film 46 may be referred to as an interlayer insulating film. The first inorganic insulating film 46 may have a laminated structure including a plurality of insulating films or may have a single layer structure constituted of a single insulating film. The first inorganic insulating film 46 preferably includes at least one film among a silicon oxide film, a silicon nitride film and a silicon oxynitride film. In this embodiment, the first inorganic insulating film 46 has a single layer structure constituted of a silicon oxide film. A thickness of the first inorganic insulating film 46 is preferably not less than 10 nm and not more than 1000 nm.

The first inorganic insulating film 46 may have a laminated structure in which a plurality of silicon oxide films are laminated. The first inorganic insulating film 46 may have a laminated structure that includes an NSG (Nondoped Silicate Glass) film and a PSG (Phosphor Silicate Glass) film laminated in that order from the first wafer main surface 42 side. The NSG film is constituted of a silicon oxide film that is not doped with an impurity. The PSG film is constituted of a silicon oxide film that is doped with phosphorous. A thickness of the NSG film may be not less than 10 nm and not more than 500 nm. A thickness of the PSG film may be not less than 10 nm and not more than 500 nm.

The first inorganic insulating film 46 may be formed by a CVD method or a thermal oxidation treatment method. The first inorganic insulating film 46 covers a functional device on the first wafer main surface 42. In this embodiment, the first inorganic insulating film 46 is also formed on a side surface of the SiC wafer 34 and the second supporting member 21 across the SiC epitaxial layer 37.

Next, with reference to FIG. 5F, a first resist mask 47 having a predetermined pattern is formed on the first inorganic insulating film 46 (Step S17 in FIG. 4). The first resist mask 47 selectively exposes each of the portions which cover a plurality of functional devices on the first inorganic insulating film 46, thereby exposing the portions which cover the intended cutting lines 45.

Next, an unnecessary portion of the first inorganic insulating film 46 is removed by an etching method via the first resist mask 47. The etching method may be a wet etching method and/or a dry etching method. Thereby, at least one contact opening 48 which selectively exposes a functional device is formed on the first inorganic insulating film 46. The first resist mask 47 is thereafter removed.

Next, with reference to FIG. 5G, a first main surface electrode 50 is formed on the first wafer main surface 42 (Step S18 in FIG. 4). The first main surface electrode 50 covers an entire area of the first inorganic insulating film 46 on the first wafer main surface 42. In this embodiment, the first main surface electrode 50 is also formed on a side surface of the SiC wafer 34 and the second supporting member 21 across the first inorganic insulating film 46. The first main surface electrode 50 may have a laminated structure that includes a Ti-based metal film and an Al-based metal film laminated in that order from the first wafer main surface 42 side. The Ti-based metal film and the Al-based metal film may be formed at least by one method among a sputtering method, a vapor deposition method and a plating method.

Next, with reference to FIG. 5H, a second resist mask 51 having a predetermined pattern is formed on the first main surface electrode 50 (Step S19 in FIG. 4). The second resist mask 51 selectively covers each of the portions which cover the plurality of device regions 44 on the first main surface electrode 50 and exposes other regions. Next, an unnecessary portion of the first main surface electrode 50 is removed by an etching method via the second resist mask 51. The etching method may be a wet etching method and/or a dry etching method. The second resist mask 51 is thereafter removed.

Next, with reference to FIG. 5I, a second inorganic insulating film 52 is formed on the first wafer main surface 42 (Step S20 in FIG. 4). The second inorganic insulating film 52 may be referred to as a passivation film. The second inorganic insulating film 52 may have a laminated structure that includes a plurality of insulating films or may have a single layer structure that is constituted of a single insulating film. The second inorganic insulating film 52 preferably includes at least one film among a silicon oxide film, a silicon nitride film and a silicon oxynitride film.

In this embodiment, the second inorganic insulating film 52 have a single layer structure constituted of a silicon nitride film. That is, the second inorganic insulating film 52 is constituted of an insulator different from the first inorganic insulating film 46. A thickness of the second inorganic insulating film 52 is preferably not less than 0.1 μm and not more than 2 μm. The second inorganic insulating film 52 may be formed by a CVD method. The second inorganic insulating film 52 covers the first main surface electrode 50 on the first wafer main surface 42. In this embodiment, the second inorganic insulating film 52 is also formed on a side surface of the SiC wafer 34 and the second supporting member 21 across the SiC epitaxial layer 37.

Next, with reference to FIG. 5J, a third resist mask 53 having a predetermined pattern is formed on the second inorganic insulating film 52 (Step S21 in FIG. 4). The third resist mask 53 exposes a portion which covers the first main surface electrode 50 and a portion which covers the intended cutting line 45 on the second inorganic insulating film 52 and covers other regions.

Next, an unnecessary portion of the second inorganic insulating film 52 is removed by an etching method via the third resist mask 53. The etching method may be a wet etching method and/or a dry etching method. Thereby, a first pad opening 54 which selectively exposes the first main surface electrode 50 and a first dicing street 55 which exposes the SiC epitaxial layer 37 along the intended cutting line 45 are formed on the second inorganic insulating film 52. A width of the first dicing street 55 may be not less than 1 μm and not more than 25 μm. The width of the first dicing street 55 is a width of a direction orthogonal to a direction in which the first dicing street 55 extends. The third resist mask 53 is thereafter removed.

Next, with reference to FIG. 5K, an organic insulating film 56 is coated on the first wafer main surface 42 (Step S22 in FIG. 4). The organic insulating film 56 may contain at least one of polyimide, polyamide and polybenzoxazole. In this embodiment, the organic insulating film 56 contains polyimide.

A thickness of the organic insulating film 56 preferably exceeds a thickness of the second inorganic insulating film 52. The thickness of the organic insulating film 56 is preferably not less than 1 μm and not more than 30 μm. The organic insulating film 56 covers the first main surface electrode 50, the first inorganic insulating film 46 and the second inorganic insulating film 52 on the first wafer main surface 42. In this embodiment, the organic insulating film 56 covers a side surface of the SiC wafer 34 and the second supporting member 21 across the SiC epitaxial layer 37.

Next, with reference to FIG. 5L, the organic insulating film 56 is exposed using a pattern corresponding to the first pad opening 54 and the first dicing street 55 of the second inorganic insulating film 52 and thereafter developed (Step S23 in FIG. 4). Thereby, a second pad opening 57 that is communicatively connected to the first pad opening 54 and a second dicing street 58 that is communicatively connected to the first dicing street 55 are formed in the organic insulating film 56. A width of the second dicing street 58 may be not less than 1 μm and not more than 25 μm. The width of the second dicing street 58 is a width of a direction orthogonal to a direction in which the second dicing street 58 extends.

Next, with reference to FIG. 5M, the SiC wafer structure 35 is supported by a third supporting member 61 from the first wafer main surface 42 side of the SiC epi-wafer 41 (Step S24 in FIG. 4). The third supporting member 61 may be adhered to the SiC wafer structure 35 by way of an adhesive agent or a double-coated adhesive tape.

The third supporting member 61 is constituted of a plate-shaped member. As long as the SiC wafer structure 35 is supported from the first wafer main surface 42 side, any type of member can be used as the third supporting member 61. The third supporting member 61 may be constituted of a material different from the SiC epi-wafer 41. The third supporting member 61 may be constituted of an inorganic plate, an organic plate, a metal plate, a crystal plate or an amorphous plate that is processed in a disk shape or a cylindrical shape. The third supporting member 61 is preferably constituted of a material which is light transmissive or transparent. In this embodiment, the third supporting member 61 is constituted of an amorphous plate. The third supporting member 61 may be constituted of a glass (silicon oxide) plate.

The third supporting member 61 has a first plate surface 62 on one side (SiC wafer structure 35 side), a second plate surface 63 on the other side and a plate side surface 64 which connects the first plate surface 62 and the second plate surface 63. The first plate surface 62 may be a ground surface, a cleavage surface, a polished surface or a mirror finished surface. The second plate surface 63 may be a ground surface, a cleavage surface, a polished surface or a mirror finished surface. Surface conditions of the first plate surface 62 and those of the second plate surface 63 are arbitrary, and the surface conditions of the second plate surface 63 are not necessarily the same as surface conditions of the first plate surface 62.

The third supporting member 61 includes a first plate edge portion 65 and a second plate edge portion 66. The first plate edge portion 65 connects the first plate surface 62 and the plate side surface 64. The first plate edge portion 65 is obliquely inclined from the first plate surface 62 toward the plate side surface 64 by chamfering. The first plate edge portion 65 may be R chamfered or C chamfered. The second plate edge portion 66 connects the second plate surface 63 and the plate side surface 64. The second plate edge portion 66 is obliquely inclined from the second plate surface 63 toward the plate side surface 64 by chamfering. The second plate edge portion 66 may be R chamfered or C chamfered.

The presence or absence of a chamfered portion in the first plate edge portion 65 and the presence or absence of a chamfered portion in the second plate edge portion 66 are arbitrary. One or both of the first plate edge portion 65 and the second plate edge portion 66 may be free of a chamfered portion and angular. However, in view of handling, it is preferable that both the first plate edge portion 65 and the second plate edge portion 66 have a chamfered portion.

The diameter and the thickness of the third supporting member 61 are arbitrary. However, in view of handling of the SiC wafer structure 35, the third supporting member 61 preferably has a diameter equal to or larger than the diameter of the SiC wafer 34. Further, the third supporting member 61 preferably has a thickness equal to or thicker than the thickness of the SiC wafer 34. In this embodiment, the third supporting member 61 has a diameter in excess of the diameter of the SiC wafer 34. A third interval 13 between a peripheral edge of the SiC wafer 34 and a peripheral edge of the third supporting member 61 when a central portion of the SiC wafer 34 overlaps a central portion of the third supporting member 61 is preferably not less than 0 mm and not more than 10 mm.

Next, with reference to FIG. 5N, a modified layer 70 along the horizontal direction parallel to the first main surface 2 is formed in the second amorphous bonding layer 32 (Step S25 in FIG. 4). In this step, a light condensing portion is set in an interior of the second amorphous bonding layer 32 or in a vicinity of the second amorphous bonding layer 32, and the second amorphous bonding layer 32 is irradiated with laser light from a laser light irradiation unit via the second supporting member 21. A position of the second amorphous bonding layer 32 irradiated with laser light is moved along the horizontal direction.

Thereby, the modified layer 70 in which a portion of the second amorphous bonding layer 32 has been modified into another property is formed at a portion of the second amorphous bonding layer 32 which is irradiated with laser light. That is, the modified layer 70 is a laser processing mark which is formed by irradiation of laser light. The modified layer 70 is constituted of a layer in which a density, a refractive index, a mechanical strength (crystal strength) or other physical characteristics have been modified to properties different from that of the second amorphous bonding layer 32 to give physical properties more fragile than that of the second amorphous bonding layer 32.

The second amorphous bonding layer 32 may include at least one layer among a melt re-hardened layer, a defect layer, a dielectric breakdown layer and a refractive index change layer. The melt re-hardened layer is a layer in which a portion of the second amorphous bonding layer 32 is re-hardened after being melted. The defect layer is a layer that includes a hole, a crack, etc., formed in the second amorphous bonding layer 32. The dielectric breakdown layer is a layer in which a portion of the second amorphous bonding layer 32 has undergone dielectric breakdown. The refractive index change layer is a layer in which a portion of the second amorphous bonding layer 32 has changed to a different refractive index.

In this embodiment, the modified layer 70 is formed also at a portion of the SiC epitaxial layer 37 which is formed on the second supporting member 21. A portion of the modified layer 70 which is formed in the SiC epitaxial layer 37 is constituted of a layer in which a density, a refractive index, a mechanical strength (crystal strength) and other physical characteristics have been modified to properties different from that of the SiC monocrystal to give physical properties more fragile than that of the SiC monocrystal.

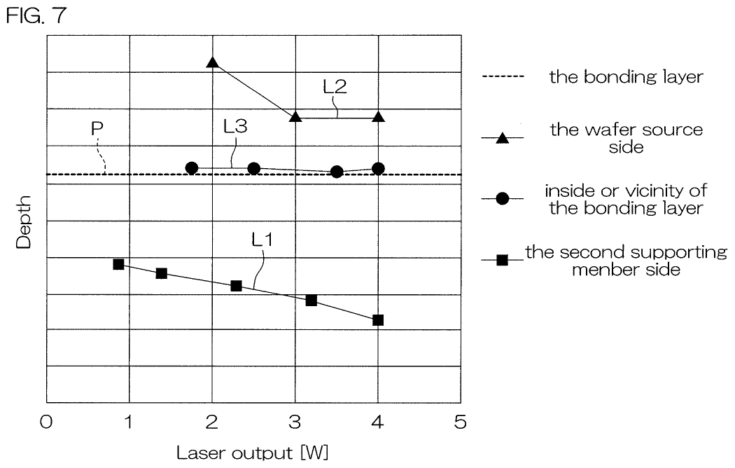

FIG. 7 is a graph for describing formation characteristics of the modified layer 70 according to the step of FIG. 5N. In FIG. 7, the vertical axis indicates a depth position (thickness position) of an interior of the SiC wafer structure 35 when the second plate surface 23 of the second supporting member 21 is given as a reference (zero point). On the other hand, the horizontal axis indicates an output [W] of laser light. Here, an irradiation target is irradiated with laser light at any given output in a range exceeding 0 W and not more than 5 W. The output of laser light is adjusted in accordance with a position, a size, etc., of the modified layer 70 to be formed and not limited to the range exceeding 0 W and not more than 5 W.

FIG. 7 shows a formation position P (refer to a dotted line portion) of the second amorphous bonding layer 32, a first polygonal line L1, a second polygonal line L2 and a third polygonal line L3. A region lower than the formation position P is the second supporting member 21, and a region higher than the formation position P is the SiC wafer 34. The first polygonal line L1 indicates a formation position of the modified layer 70 where an interior of the second supporting member 21 is irradiated with laser light. The second polygonal line L2 indicates a formation position of the modified layer 70 where an interior of the SiC wafer 34 is irradiated with laser light.

The third polygonal line L3 indicates a formation position of the modified layer 70 when the interior, or the vicinity of the second amorphous bonding layer 32 is irradiated with laser light. The vicinity of the second amorphous bonding layer 32 refers to a thickness range within ±50 μm from the formation position P of the second amorphous bonding layer 32. The vicinity of the second amorphous bonding layer 32 is preferably set in a thickness range within ±10 μm from the formation position P.

With reference to the first polygonal line L1, when the interior of the second supporting member 21 is irradiated with laser light, in association with an increase in output of laser light, the formation position of the modified layer 70 is shifted from the first plate surface 22 side to the second plate surface 23 side. With reference to the second polygonal line L2, when the interior of the SiC wafer 34 is irradiated with laser light, in association with an increase in output of laser light, the formation position of the modified layer 70 is shifted from the first wafer main surface 42 side to the second wafer main surface 43 side.

In contrast thereto, with reference to the third polygonal line L3, when the interior, or the vicinity of the second amorphous bonding layer 32 is irradiated with laser light, despite an increase in output of laser light, the formation position of the modified layer 70 is kept substantially in a certain thickness range. That is, when the interior, or the vicinity of the second amorphous bonding layer 32 is irradiated with laser light, a variation in formation position of the modified layer 70 in relation to an output of laser light is suppressed, thus making it possible to form the modified layer 70 with a high accuracy. This is because a light absorption coefficient of the modified layer 70 is larger than the light absorption coefficient of the SiC wafer 34 and a light absorption coefficient of the second supporting member 21.

Next, with reference to FIG. 5O, the SiC wafer structure 35 is cut from a thickness direction intermediate portion along the horizontal direction with the modified layer 70 (second amorphous bonding layer 32) as a starting point, and the SiC epi-wafer 41 (SiC wafer 34) is cut away from the second supporting member 21 (Step S26 in FIG. 4). In this step, an external force is applied to the second amorphous bonding layer 32 in a state of being held between the second supporting member 21 and the third supporting member 61, and the SiC wafer source 1 is cleaved in the horizontal direction with the modified layer 70 as a starting point. The external force applied to the second amorphous bonding layer 32 may be ultrasonic waves.

The second supporting member 21 may be reused as the second supporting member 21 for supporting the same SiC wafer source 1 or another SiC wafer source 1 after being separated from the SiC epi-wafer 41. When the second supporting member 21 is reused, a bonding surface (first plate surface 22) is preferably flattened (smoothed) by a grinding method and/or an etching method. The SiC epi-wafer 41 (SiC wafer 34) and/or the second amorphous bonding layer 32 (modified layer 70) remaining on the first plate surface 22 of the second supporting member 21 may be removed by a grinding method and/or an etching method. A grinding step may be implemented by a CMP method. The grinding step may include a polishing step or a mirror finishing step of the first plate surface 22.

Next, with reference to FIG. 5P, a section plane of the SiC epi-wafer 41 (cleavage surface/second wafer main surface 43) is flattened (smoothed) in a state of being supported by the third supporting member 61 by a grinding method and/or an etching method (Step S27 in FIG. 4). A grinding step may be implemented by a CMP method. The grinding step may include a polishing step or a mirror finishing step of the second wafer main surface 43.

Next, with reference to FIG. 5Q, a second main surface electrode 71 is formed on the second wafer main surface 43 (Step S28 in FIG. 4). In this embodiment, the second main surface electrode 71 is also formed on a portion of the SiC epitaxial layer 37 which covers aside surface of the SiC wafer 34. The second main surface electrode 71 forms an ohmic contact with the second wafer main surface 43. The second main surface electrode 71 may include at least one film among a Ti film, an Ni film, a Pd film, an Au film and an Ag film.

The second main surface electrode 71 may include at least a Ti film, and the presence or absence of an Ni film, a Pd film, an Au film and an Ag film and a lamination order are arbitrary. The second main surface electrode 71 may include, as an example, a Ti film, an Ni film, a Pd film and an Au film which are laminated in that order from the second wafer main surface 43 side. As another example, the second main surface electrode 71 may have a laminated structure which includes a Ti film, an Ni film and an Au film. A Ti film, an Ni film, a Pd film, an Au film and an Ag film may be formed at least by one of a sputtering method, a vapor deposition method and a plating method (in this embodiment, a sputtering method).

The second main surface electrode 71 preferably includes a Ti film as an ohmic electrode which is directly connected to the second wafer main surface 43. In this case, an annealing treatment may be given to the second wafer main surface 43 by a laser irradiation method via a Ti film. In this step, an annealing mark is formed on the second wafer main surface 43. The annealing mark may contain amorphized SiC and/or SiC (specifically, Si) that has been silicided (alloyed) with a metal (Ti). Thereby, the second wafer main surface 43 is given as an ohmic surface which has a grinding mark and an annealing mark (laser irradiation mark). After formation of the second main surface electrode 71, the third supporting member 61 is removed from the SiC epi-wafer 41.

Next, with reference to FIG. 5R, the SiC epi-wafer 41 is cut along an intended cutting line 45 (Step S29 in FIG. 4). The cutting step of the SiC epi-wafer 41 may include a cutting step by a dicing blade. In this case, the SiC epi-wafer 41 is cut along the intended cutting lines 45 demarcated by the first dicing street 55 (second dicing street 58). The dicing blade preferably has a blade width less than a width of the first dicing street 55 (second dicing street 58). The first inorganic insulating film 46, the second inorganic insulating film 52 and the organic insulating film 56 are not positioned on the intended cutting lines 45 and thereby avoid the dicing by the dicing blade.

The cutting step of the SiC epi-wafer 41 may include a cleaving step using a laser light irradiation method. In this case, an interior of the SiC epi-wafer 41 is irradiated with laser light from a laser light irradiation unit (not shown) via the first dicing street 55 (second dicing street 58). Preferably, the interior of the SiC epi-wafer 41 is irradiated in pulses with laser light from the first wafer main surface 42 side which does not have the second main surface electrode 71. A light condensing portion (focal point) of the laser light is set in the interior of the SiC epi-wafer 41 (thickness direction intermediate portion) and an irradiation position of the laser light is moved along the intended cutting line 45.

Thereby, the modified layer extending in a lattice along the intended cutting lines 45 (first dicing street 55) in a plan view is formed in the interior of the SiC epi-wafer 41. The modified layer is preferably formed at an interval from the first wafer main surface 42 in the interior of the SiC epi-wafer 41. The modified layer is preferably formed in a portion constituted of the SiC wafer 34 in the interior of the SiC epi-wafer 41. The modified layer is in particular preferably formed at an interval from the SiC epitaxial layer 37 in the SiC wafer 34. Most preferably, the modified layer is not formed in the SiC epitaxial layer 37.

After the step of forming the modified layer, an external force is applied to the SiC epi-wafer 41, and the SiC epi-wafer 41 is cleaved with the modified layer as a starting point. The external force is preferably applied to the SiC epi-wafer 41 from the second wafer main surface 43 side. The second main surface electrode 71 is cleaved at the same time with cleavage of the SiC epi-wafer 41. The first inorganic insulating film 46, the second inorganic insulating film 52 and the organic insulating film 56 are not positioned on the intended cutting lines 45 and thereby avoid the cleavage. The SiC semiconductor device is manufactured through the steps including the above.

As described so far, the SiC semiconductor device manufacturing method includes a step which prepares the SiC wafer source 1 (Step S1 in FIG. 2), a step which supports the SiC wafer source 1 by the second supporting member 21 (Step S3 in FIG. 2) and a step which separates the SiC wafer structure 35 from the SiC wafer source 1 (Step S5 in FIG. 2). In the preparation step, prepared is the SiC wafer source 1 which includes the first main surface 2 on one side and the second main surface 3 on the other side. In the supporting step, the SiC wafer source 1 is supported by the second supporting member 21 from the second main surface 3 side.

In the separating step, the SiC wafer source 1 is cut in the horizontal direction from a thickness direction intermediate portion along the first main surface 2, and the SiC wafer structure 35 which includes the second supporting member 21 and the SiC wafer 34 cut away from the SiC wafer source 1 is separated from the SiC wafer source 1. According to the manufacturing method, it is possible to efficiently separate the SiC wafer structure 35 from the SiC wafer source 1. Further, according to the SiC wafer structure 35, the SiC wafer 34 is handled integrally with the second supporting member 21, by which the SiC wafer 34 can be handled with an improved convenience. Accordingly, it is possible to provide the SiC semiconductor device manufacturing method capable of improving the manufacturing efficiency and the SiC wafer structure 35.

The SiC wafer source 1 is preferably constituted of an SiC monocrystal (4H—SiC monocrystal) that is a hexagonal crystal. The SiC wafer source 1 is preferably cut out from an SiC ingot (SiC monocrystal mass) that is a hexagonal crystal by a slice processing method. The SiC wafer source 1 is in particular preferably constituted of an SiC wafer for device formation cut out from the SiC ingot. The SiC wafer source 1 preferably has such a thickness that at least one (preferably a plurality of) SiC wafers 34 for device formation can be cut out until it becomes unable to be separated.

The SiC wafer source 1 may have a diameter of not less than 25 mm and not more than 300 mm (that is, not less than 1 inch and not more than 12 inches). The SiC wafer source 1 may have a thickness of not less than 0.1 mm and not more than 50 mm. The thickness of the SiC wafer source 1 is typically not more than 20 mm. When the SiC wafer source 1 is cut out from an SiC ingot as an SiC wafer for device formation, the thickness of the SiC wafer source 1 may be not less than 0.3 mm and not more than 15 mm (preferably not more than 10 mm). In this case, the diameter of the SiC wafer source 1 may be not less than 2 inches and not more than 12 inches.

The second supporting member 21 is preferably constituted of a plate-shaped member which supports the SiC wafer source 1 from the second main surface 3 side. The second supporting member 21 is preferably constituted of a light transmissive or transparent material which suppresses attenuation of laser light. A melting point of the second supporting member 21 is preferably equal to or higher than a melting point of the SiC wafer source 1. In this case, it is possible to suppress melting and deformation of the second supporting member 21 in a manufacturing process.

A ratio of thermal expansion coefficient of the second supporting member 21 in relation to thermal expansion coefficient of the SiC wafer source 1 is preferably not less than 0.5 and not more than 1.5. In this case, it is possible to reduce a difference in stress occurring between stress on the SiC wafer 34 side and stress on the second supporting member 21 side in a manufacturing process. It is, thus, possible to suppress warping of the SiC wafer 34.

The second supporting member 21 is in particular preferably constituted of the same material (that is, SiC) as the SiC wafer source 1. In this case, the second supporting member 21 may be constituted of an SiC monocrystal or an SiC polycrystal. When the second supporting member 21 is constituted of an SiC monocrystal, the second supporting member 21 is preferably constituted of an SiC monocrystal (4H—SiC monocrystal) that is a hexagonal crystal. The second supporting member 21 is preferably constituted of a disk-shaped or cylindrical-shaped wafer cut out from an SiC ingot (SiC monocrystal mass) which is a hexagonal crystal by a slice processing method.

The second supporting member 21 preferably has a diameter equal to or larger than a diameter of the SiC wafer source 1. In this case, not only can an improved convenience of handling be attained but also the SiC wafer source 1 (SiC wafer 34) can be protected appropriately by the second supporting member 21. The second supporting member 21 preferably has a thickness equal to or thicker than a thickness of the SiC wafer 34. The second supporting member 21 preferably has a thickness equal to or thicker than a thickness of the SiC wafer source 1. The second interval 12 between the peripheral edge of the SiC wafer source 1 and the peripheral edge of the second supporting member 21 when the central portion of the SiC wafer source 1 overlaps the central portion of the second supporting member 21 is preferably not less than 0 mm and not more than 10 mm.

The manufacturing method preferably includes a step which transfers the SiC wafer structure 35 after the separating step. According to this step, the SiC wafer 34 and the second supporting member 21 can be transferred in an integral manner. It is, thereby, possible to improve the convenience of handling.

The manufacturing method preferably includes the reusing step of the SiC wafer source 1 (Steps S3 to S8 in FIG. 2) in which a series of steps including the supporting step and the separating step are repeated until the SiC wafer source 1 becomes unable to be separated. According to this step, it is possible to efficiently consume the SiC wafer source 1 and also increase the number of SiC semiconductor devices which can be obtained from one SiC wafer source 1. It is, thereby, possible to reduce manufacturing costs and improve the manufacturing efficiency.

In the manufacturing method, the step of cutting the SiC wafer source 1 preferably includes a step in which the SiC wafer source 1 is cleaved in the horizontal direction with the modified layer 70 as a starting point, after the modified layer 70 along the horizontal direction has been formed at the thickness direction intermediate portion of the SiC wafer source 1 by a laser light irradiation method (Steps S4 to S5 in FIG. 2). According to this step, there is eliminated a necessity for cutting the SiC wafer source 1 by grinding. Further, the SiC wafer source 1 can be in advance cleaved in a thickness according to such a thickness of the SiC semiconductor device that is to be manufactured. It is, thus, possible to suppress an excessive consumption of the SiC wafer source 1 and also reduce costs resulting from grinding. Thereby, the manufacturing efficiency can be improved.

The SiC wafer source 1 preferably includes the second edge portion 6 which is at least angular. When the second edge portion 6 of the SiC wafer source 1 has a chamfered portion, a gap is formed between the second edge portion 6 and the second supporting member 21. Errors that occur at the light condensing portion (focus) of laser light include an error resulting from this gap. Therefore, the second edge portion 6 of the SiC wafer source 1 is made angular, and it is possible to suppress a gap between the SiC wafer source 1 and the second supporting member 21. Accordingly, an interior of the SiC wafer source 1 can be appropriately irradiated with laser light to form the modified layer 70 appropriately.

The manufacturing method may include a step which forms the SiC epitaxial layer 37 on a section plane of the SiC wafer 34 (Step S13 in FIG. 4). According to this step, after the SiC wafer structure 35 has been obtained, the SiC epitaxial layer 37 can be continuously formed on the section plane of the SiC wafer 34. It is, thereby, possible to improve the manufacturing efficiency. Preferably, the manufacturing method includes a step of polishing the section plane of the SiC wafer 34 and the SiC epitaxial layer 37 is formed on the polished surface of the SiC wafer 34 (Steps S12 to S13 in FIG. 4). According to this step, the SiC epitaxial layer 37 can be formed appropriately.

The manufacturing method may include a step of forming a functional device on the section plane of the SiC wafer 34 (Steps S11 to S23 in FIG. 4). According to this step, after the SiC wafer structure 35 has been obtained, the functional device can be continuously formed on the section plane of the SiC wafer 34. It is, thereby, possible to improve the manufacturing efficiency. The functional device may include at least one or both of an SiC-SBD and an SiC-MISFET.

Preferably, the manufacturing method includes the step of polishing the section plane of the SiC wafer 34 and a functional device is formed on the polished surface of the SiC wafer 34 (Steps S12 to S13 in FIG. 4). According to this step, it is possible to form appropriately the functional device.

The manufacturing method may include a step of removing the second supporting member 21 from the SiC wafer 34 after formation of the functional device (Step S26 in FIG. 4). The second supporting member 21 is preferably bonded to the second main surface 3 of the SiC wafer source 1 by the direct bonding method (Step S3 in FIG. 2). In this case, the SiC wafer structure 35 which has the second amorphous bonding layer 32 between the SiC wafer 34 and the second supporting member 21 is formed. The second amorphous bonding layer 32 preferably has a light absorption coefficient larger than a light absorption coefficient of the SiC wafer 34. The light absorption coefficient of the second amorphous bonding layer 32 is preferably larger than the light absorption coefficient of the second supporting member 21.

The step of removing the second supporting member 21 preferably includes a step which forms the modified layer 70 in the second amorphous bonding layer 32 by a laser light irradiation method and a step which cleaves the SiC wafer structure 35 with the modified layer 70 as a starting point (Steps S25 to S26 in FIG. 2). According to this step, it is possible to separate the SiC wafer 34 and the second supporting member 21. Further, according to this step, there is eliminated a necessity for cutting the SiC wafer structure 35 by grinding. It is, thereby, possible to suppress an excessive consumption of the SiC wafer structure 35 and also reduce costs resulting from the grinding. It is, thereby, possible to improve the manufacturing efficiency.

In this step, the interior of the second amorphous bonding layer 32 or the vicinity of the second amorphous bonding layer 32 is preferably irradiated with laser light. According to this step, it is possible to form accurately the modified layer 70 in the interior of, or in the vicinity of the second amorphous bonding layer 32. That is, it is possible to suppress appropriately formation of the modified layer 70 in one or both of the SiC wafer 34 and the second supporting member 21 by irradiation of laser light.

Thereby, it is possible to suppress a variation in physical properties and electrical properties of the SiC wafer 34 due to the modified layer 70 and, therefore, manufacture appropriately the SiC semiconductor device from the SiC wafer 34. It is also possible to suppress a variation in physical properties and electrical properties of the second supporting member 21 due to the modified layer 70 and, therefore, reuse appropriately the second supporting member 21.

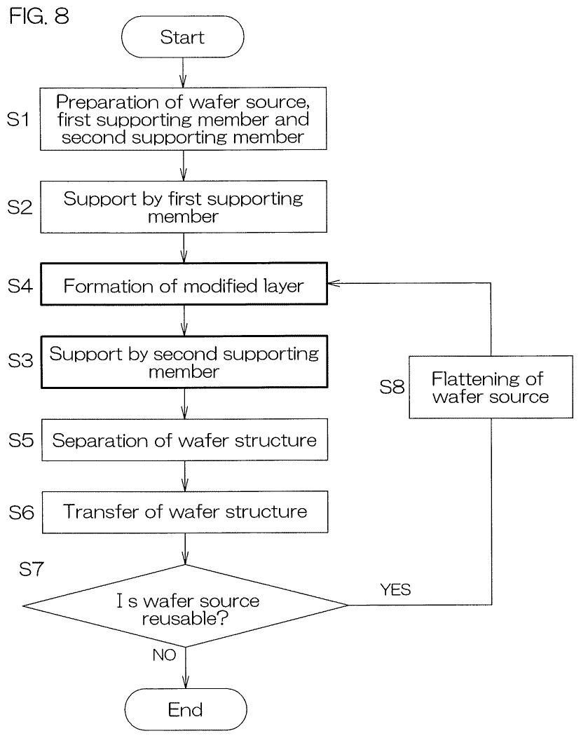

FIG. 8 is a flowchart showing one example of an SiC semiconductor device manufacturing method according to a second preferred embodiment of the present invention. In the SiC semiconductor device manufacturing method according to the first preferred embodiment, after the SiC wafer source 1 has been supported by the second supporting member 21, the modified layer 33 is formed in the SiC wafer source 1 (Steps S3 to S4 in FIG. 2). In contrast thereto, in the manufacturing method according to the second preferred embodiment, after a modified layer 33 has been formed in an interior of an SiC wafer source 1, an SiC wafer 34 is supported by a second supporting member 21 (Steps S3 to S4 in FIG. 8).

That is, according to the manufacturing method of the second preferred embodiment, prior to a supporting step by the second supporting member 21, the inner portion of the SiC wafer source 1 is directly irradiated with laser light from a second main surface 3 side of the SiC wafer source 1 (Step S4 in FIG. 8). Thereafter, the SiC wafer source 1 having the modified layer 33 is supported from the second main surface 3 side by the second supporting member 21 (Step S3 in FIG. 8). Therefore, it is possible to suppress attenuation of laser light resulting from the second supporting member 21 and form appropriately the modified layer 33 in the interior of the SiC wafer source 1.

When the SiC wafer source 1 is reusable (Step S7 in FIG. 8: YES), a step of reusing the SiC wafer source 1 is implemented. In the step of reusing the SiC wafer source 1, the second main surface 3 (cleavage surface) of the SiC wafer source 1 is flattened (smoothed) in a state of being supported by a first supporting member 11 by a grinding method and/or an etching method (Step S8 in FIG. 8). A grinding step may be implemented by a CMP method. The grinding step may include a polishing step or a mirror finishing step of the second main surface 3.

Next, after the modified layer 33 has been formed in the interior of the SiC wafer source 1, the SiC wafer source 1 is supported by the second supporting member 21 (Steps S3 to S4 in FIG. 8). In the manufacturing method according to the second preferred embodiment, as with the manufacturing method according to the first preferred embodiment, the step of reusing the SiC wafer source 1 is repeatedly implemented until the SiC wafer source 1 becomes unable to be separated. Steps S11 to S29 shown in FIG. 4 are implemented with respect to the SiC wafer structure 35 which is obtained from the SiC wafer source 1.

As described so far, the SiC semiconductor device manufacturing method according to the second preferred embodiment is also able to provide the same effects as those described in the SiC semiconductor device manufacturing method according to the first preferred embodiment.

The present invention can be implemented in still other embodiments.

In each of the aforementioned preferred embodiments, a description has been given of an example in which the SiC wafer source 1 is used. However, in place of the SiC wafer source 1, there may be adopted a WBG (Wide Bandgap) wafer source which is constituted of a WBG semiconductor other than SiC. The WBG semiconductor is a semiconductor which has a bandgap in excess of a bandgap of Si (silicon). Examples of the WBG semiconductor include GaN (gallium nitride), diamond, etc. As a matter of course, in the aforementioned preferred embodiments, in place of the SiC wafer source 1, there may be adopted an Si wafer source which is constituted of Si (silicon).

In each of the aforementioned preferred embodiments, a description has been given of an example in which the step of supporting the SiC wafer source 1 by the second supporting member 21 (Step S2 in FIG. 2 and FIG. 8) is implemented after the step of supporting the SiC wafer source 1 by the first supporting member 11 (Step S1 in FIG. 2 and FIG. 8). However, the step of supporting the SiC wafer source 1 by the second supporting member 21 may be implemented prior to the step of supporting the SiC wafer source 1 by the first supporting member 11.

In each of the aforementioned preferred embodiments, a description has been given of an example in which the SiC wafer source 1 is supported by the first supporting member 11 from the first main surface 2 side (refer to Step S2 in FIG. 2, and FIG. 3B, etc.). However, the SiC wafer source 1 is not necessarily required to be supported by the first supporting member 11. For example, when there is used a tool which supports or holds the SiC wafer source 1 from the side surface 4 side, a step of supporting the SiC wafer source 1 by the first supporting member 11 may be omitted. That is, in place of the step of supporting the SiC wafer source 1 by the first supporting member 11, there may be implemented a step of supporting the SiC wafer source 1 by a tool which supports or holds the SiC wafer source 1 from the side surface 4 side.

In each of the aforementioned preferred embodiments, a description has been given of an example in which the first supporting member 11 is constituted of a material (amorphous plate) different from the SiC wafer source 1. However, in each of the aforementioned preferred embodiments, there may be adopted a first supporting member 11 which has a mode similar to that of the second supporting member 21. In this case, a description of the second supporting member 21 will be applied to a description of a specific mode of the first supporting member 11.

In each of the aforementioned preferred embodiments, the first edge portion 5 or the second edge portion 6 of the SiC wafer source 1 is not chamfered. However, there may be adopted such a mode that while the first edge portion 5 is chamfered, the second edge portion 6 is not chamfered. In this case, the first edge portion 5 may be obliquely inclined from a first main surface 2 toward a side surface 4. In this case, the first edge portion 5 may be R chamfered or C chamfered.

In each of the aforementioned preferred embodiments, the SiC wafer source 1 has the first orientation flat 7 as one example of a mark for indicating the crystal orientation of the SiC monocrystal. However, the SiC wafer source 1 may have an orientation notch as one example of a mark for indicating the crystal orientation of the SiC monocrystal in place of the first orientation flat 7.

The orientation notch may be constituted of a triangular notch portion which is depressed from the side surface 4 toward a central portion. The orientation notch may be depressed in an a-axis direction of the SiC monocrystal. The orientation notch is not necessarily required to be depressed in the a-axis direction and may be depressed in an m-axis direction. As a matter of course, the SiC wafer source 1 may have an orientation notch depressed in the a-axis direction and an orientation notch depressed in the m-axis direction.

In each of the aforementioned preferred embodiments, the second supporting member 21 has the second orientation flat 27 as one example of a mark for indicating the crystal orientation of the SiC monocrystal (the crystal orientation of the SiC wafer source 1). However, the second supporting member 21 may have an orientation notch as one example of a mark for indicating the crystal orientation of the SiC monocrystal (the crystal orientation of the SiC wafer source 1) in place of the second orientation flat 27.

The orientation notch may be constituted of a triangular notch portion which is depressed from the plate side surface 24 toward the central portion. The orientation notch may be depressed in the a-axis direction of the SiC monocrystal. The orientation notch is not necessarily required to be depressed in the a-axis direction and may be depressed in the m-axis direction. As a matter of course, the second supporting member 21 may have an orientation notch which is depressed in the a-axis direction and an orientation notch which is depressed in the m-axis direction. Further, in each of the aforementioned preferred embodiments, there may be used a second supporting member 21 which is free of a second orientation flat 27 (orientation notch).

In each of the aforementioned preferred embodiments, a description has been given of an example in which the SiC wafer structure 35 is supported by the third supporting member 61 from the first wafer main surface 42 side (refer to Step S24 in FIG. 4, and FIG. 5M, etc.). However, the SiC wafer structure 35 is not necessarily required to be supported by the third supporting member 61. For example, where a tool for supporting or holding the SiC wafer structure 35 from the side surface 4 side is used, a step of supporting the SiC wafer structure 35 by the third supporting member 61 may be omitted. That is, there may be implemented a step of supporting the SiC wafer structure 35 by a tool which supports or holds the SiC wafer structure 35 from the side surface 4 side in place of the step of supporting the SiC wafer structure 35 by the third supporting member 61.

In each of the aforementioned preferred embodiments, a description has been given of an example in which the interior, or the vicinity of the second amorphous bonding layer 32 is irradiated with laser light to form the modified layer 70 along the horizontal direction parallel to the first main surface 2 (refer to Step S25 in FIG. 4, and FIG. 5N, etc.). However, the modified layer 70 is preferably formed in the interior or in the vicinity of the second amorphous bonding layer 32 but not necessarily required to be formed in the interior or in the vicinity of the second amorphous bonding layer 32.

For example, a thickness direction intermediate portion of the SiC epi-wafer 41 (SiC wafer 34) is irradiated with laser light, by which the modified layer 70 along the horizontal direction parallel to the first main surface 2 may be formed at the thickness direction intermediate portion of the SiC epi-wafer 41 (SiC wafer 34). The interior of the SiC epi-wafer 41 (SiC wafer 34) may be irradiated with laser light via the second supporting member 21 and the second amorphous bonding layer 32.

In this case, the modified layer 70 is preferably formed in a region of the SiC epi-wafer 41 between the second amorphous bonding layer 32 and the SiC epitaxial layer 37. That is, the modified layer 70 is preferably formed only in the SiC wafer 34. According to this step, it is possible to subsequently adjust the thickness of the SiC epi-wafer 41 (SiC wafer 34) by using a step of removing the second supporting member 21 even after the SiC wafer structure 35 has been obtained.

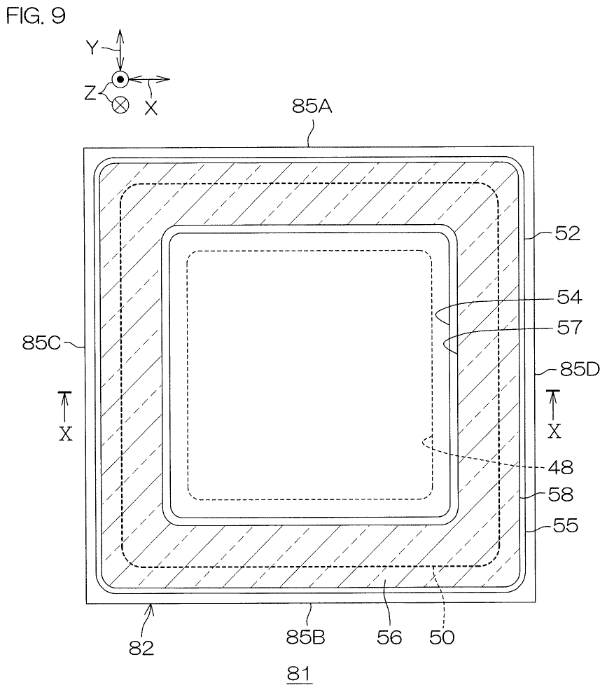

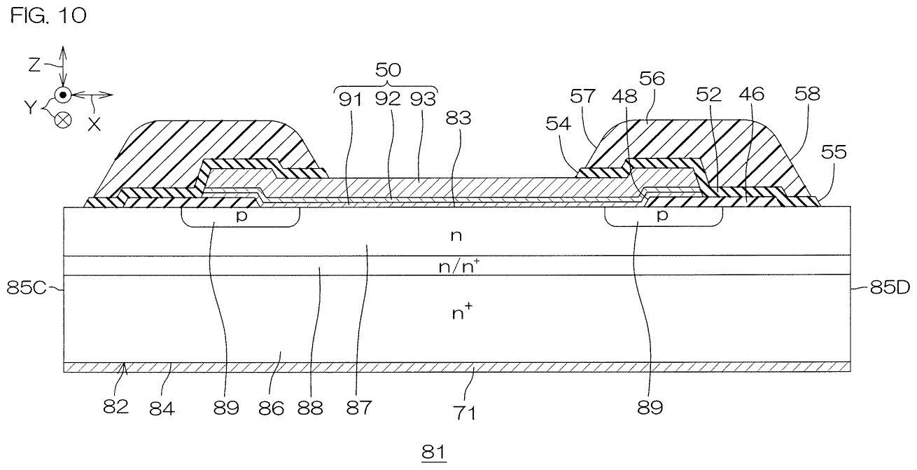

FIG. 9 is a plan view showing an SiC semiconductor device (hereinafter, referred to as an “SiC semiconductor device 81”) which has a functional device according to one configuration example. FIG. 10 is a cross-sectional view along line X-X shown in FIG. 9.

With reference to FIG. 9 and FIG. 10, the SiC semiconductor device 81 includes an SiC-SBD as one example of the functional device. The SiC semiconductor device 81 includes an SiC chip 82 which is constituted of an SiC monocrystal that is a hexagonal crystal. The SiC chip 82 is constituted of an individual piece of an SiC epi-wafer 41 and formed in a rectangular parallelepiped shape. The SiC chip 82 has a first main surface 83 on one side, a second main surface 84 on the other side and first to fourth side surfaces 85A to 85D which connect the first main surface 83 and the second main surface 84.

The first main surface 83 and the second main surface 84 are formed in a quadrilateral shape in a plan view as viewed in a normal direction Z thereto (hereinafter, referred to simply as “in a plan view”). The first main surface 83 and the second main surface 84 are arranged along c-planes of the SiC monocrystal. Preferably, the first main surface 83 is arranged along a silicon plane and the second main surface 84 is arranged along a carbon plane.

When the SiC epi-wafer 41 has an off angle, the first main surface 83 and the second main surface 84 each have an off angle corresponding to the off angle of the SiC epi-wafer 41. The second main surface 84 may be constituted of a rough surface having one or both of a grinding mark and an annealing mark (specifically, a laser irradiation mark). The annealing mark may contain amorphized SiC and/or SiC (specifically, Si) that has been silicided (alloyed) with a metal (Ti).

The first side surface 85A and the second side surface 85B extend in a first direction X along the first main surface 83 and face each other in a second direction Y intersecting (specifically, orthogonal to) the first direction X. The third side surface 85C and the fourth side surface 85D extend in the second direction Y and face each other in the first direction X. In this embodiment, the first direction X is an m-axis direction ([1-100] direction) of the SiC monocrystal and the second direction Y is an a-axis direction of the SiC monocrystal.

The SiC semiconductor device 81 includes an n-type (first conductive type) first semiconductor region 86 (high concentration region) which is formed in a surface layer portion of the second main surface 84. The first semiconductor region 86 forms a cathode of an SiC-SBD. The first semiconductor region 86 may be referred to as a cathode region.

The first semiconductor region 86 has an n-type impurity concentration which is substantially constant in the thickness direction. The first semiconductor region 86 is formed across an entire area of the surface layer portion of the second main surface 84. That is, the first semiconductor region 86 has the second main surface 84 and portions of the first to fourth side surfaces 85A to 85D. The first semiconductor region 86 is formed of an n-type SiC substrate constituted of a part of an SiC wafer 34.

The SiC semiconductor device 81 includes an n-type second semiconductor region 87 (low concentration region) formed in the surface layer portion of the first main surface 83. The second semiconductor region 87 has an n-type impurity concentration less than an n-type impurity concentration of the first semiconductor region 86. The second semiconductor region 87 is electrically connected to the first semiconductor region 86 and forms a cathode of the SiC-SBD together with the first semiconductor region 86. The second semiconductor region 87 may be referred to as a drift region. The second semiconductor region 87 is formed across an entire area of the surface layer portion of the first main surface 83 and has the first main surface 83 and portions of the first to fourth side surfaces 85A to 85D. The second semiconductor region 87 is formed of an n-type SiC epitaxial layer 37.

The SiC semiconductor device 81 includes an n-type third semiconductor region 88 (concentration transition region) that is interposed between the first semiconductor region 86 and the second semiconductor region 87 in the SiC chip 82. The third semiconductor region 88 has a concentration gradient in which an n-type impurity concentration decreases (specifically, decreases gradually) from the n-type impurity concentration of the first semiconductor region 86 toward the n-type impurity concentration of the second semiconductor region 87. The third semiconductor region 88 is interposed over an entire area between the first semiconductor region 86 and the second semiconductor region 87 and has portions of the first to fourth side surfaces 85A to 85D.

The third semiconductor region 88 forms a cathode of the SiC-SBD together with the first semiconductor region 86 and the second semiconductor region 87. The third semiconductor region 88 may be referred to as a buffer region. The third semiconductor region 88 is constituted of the n-type SiC epitaxial layer 37.

The SiC semiconductor device 81 includes a p-type (second conductive type) guard region 89 which is formed in a surface layer portion of the first main surface 83. The guard region 89 is formed in the first main surface 83 at an interval inward from peripheral edges (the first to fourth side surfaces 85A to 85D) of the first main surface 83 to expose an inner portion of the first main surface 83. In this embodiment, the guard region 89 is formed in a quadrilateral annular shape that surrounds the inner portion of the first main surface 83 in a plan view.

The SiC semiconductor device 81 includes a first inorganic insulating film 46 which is formed on the first main surface 83. In this embodiment, the first inorganic insulating film 46 is constituted of a field oxide film that contains an oxide of the SiC chip 82 (second semiconductor region 87). The first inorganic insulating film 46 is formed in a quadrilateral annular shape that surrounds an inner portion of the first main surface 83 in a plan view and has contact openings 48 which expose inner edge portions of the second semiconductor region 87 and the guard region 89.

The contact opening 48 is formed in a quadrilateral shape having four sides parallel to a peripheral edge of the first main surface 83 in a plan view. The first inorganic insulating film 46 covers an outer edge portion of the guard region 89 over an entire periphery in a plan view to expose an inner edge portion of the guard region 89 over an entire periphery. The first inorganic insulating film 46 is formed at an interval toward an inner side of the first main surface 83 from the peripheral edge of the first main surface 83 to expose a peripheral edge portion (second semiconductor region 87) of the first main surface 83.

The SiC semiconductor device 81 includes a first main surface electrode 50 which forms a Schottky bonding with the first main surface 83 inside the contact opening 48. Thereby, formed is the SiC-SBD that includes the first main surface electrode 50 as an anode and the second semiconductor region 87 as a cathode. The first main surface electrode 50 is formed in a quadrilateral shape having four sides parallel to the peripheral edge of the first main surface 83 in a plan view. The first main surface electrode 50 includes a lead-out portion which is led out on the first inorganic insulating film 46. The lead-out portion faces the guard region 89 across the first inorganic insulating film 46.

In this embodiment, the first main surface electrode 50 has a laminated structure which includes a first electrode film 91, a second electrode film 92 and a third electrode film 93 laminated in that order from the SiC chip 82 side. The first electrode film 91 is formed as a film along the first main surface 83 and the main surface of the first inorganic insulating film 46. The first electrode film 91 is constituted of a Schottky barrier electrode film and forms a Schottky bonding with the first main surface 83 (second semiconductor region 87). An electrode material of the first electrode film 91 is arbitrary as long as a Schottky bonding is formed with the first main surface 83 (second semiconductor region 87). In this embodiment, the first electrode film 91 is constituted of a titanium film.

The second electrode film 92 is constituted of a metal barrier film which is formed as a film on the first electrode film 91. The second electrode film 92 may be constituted of a Ti-based metal film. In this embodiment, the second electrode film 92 includes a titanium nitride film. The third electrode film 93 is formed as a film along a main surface of the second electrode film 92. The third electrode film 93 is constituted of a Cu-based metal film or an Al-based metal film. The third electrode film 93 may include at least one film among a pure Cu film (a Cu film with a purity of not less than 99%), a pure Al film (an Al film with a purity of not less than 99%), an AlCu alloy film, an AlSi alloy film and an AlSiCu alloy film.

The SiC semiconductor device 81 includes a second inorganic insulating film 52 which selectively covers the first main surface 83, the first inorganic insulating film 46 and the first main surface electrode 50. The second inorganic insulating film 52 has a first pad opening 54 which exposes the first main surface electrode 50. The first pad opening 54 is formed in a quadrilateral shape having four sides parallel to the peripheral edge of the first main surface 83 in a plan view. The second inorganic insulating film 52 has a first dicing street 55 which exposes the peripheral edge portion of the first main surface 83 together with the peripheral edge of the first main surface 83. The first dicing street 55 is demarcated in a quadrilateral annular shape extending along the peripheral edge of the first main surface 83.

The SiC semiconductor device 81 includes an organic insulating film 56 that is formed on the second inorganic insulating film 52. The organic insulating film 56 has a second pad opening 57 which is communicatively connected to the first pad opening 54 to expose the first main surface electrode 50. The second pad opening 57 is formed in a quadrilateral shape having four sides parallel to the peripheral edge of the first main surface 83 in a plan view. The organic insulating film 56 has a second dicing street 58 which exposes the peripheral edge of the first main surface 83, together with the first dicing street 55. The second dicing street 58 is demarcated in a quadrilateral annular shape extending along the peripheral edge of the first main surface 83.

The SiC semiconductor device 81 includes a second main surface electrode 71 which covers the second main surface 84. The second main surface electrode 71 may be referred to as a cathode electrode. The second main surface electrode 71 covers an entire area of the second main surface 84 and continues to the peripheral edge (first to fourth side surfaces 85A to 85D) of the first main surface 83. The second main surface electrode 71 forms an ohmic contact with the first semiconductor region 86 (second main surface 84).

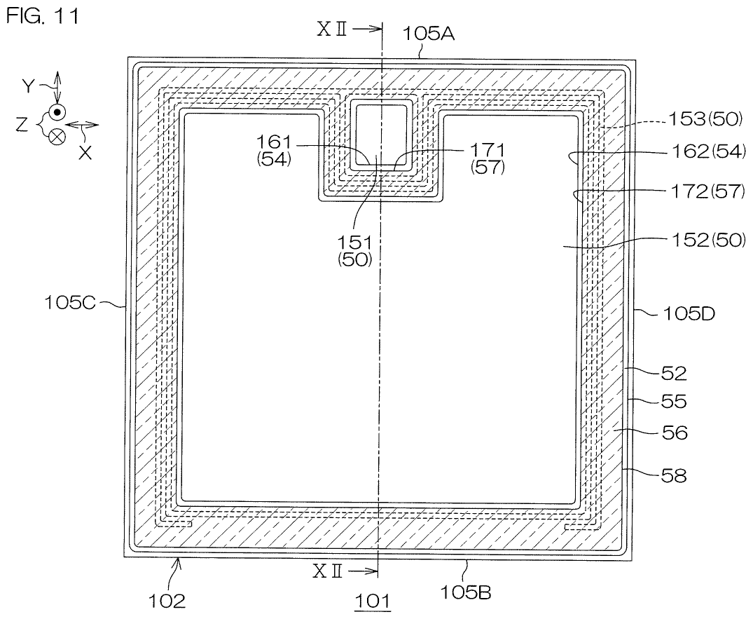

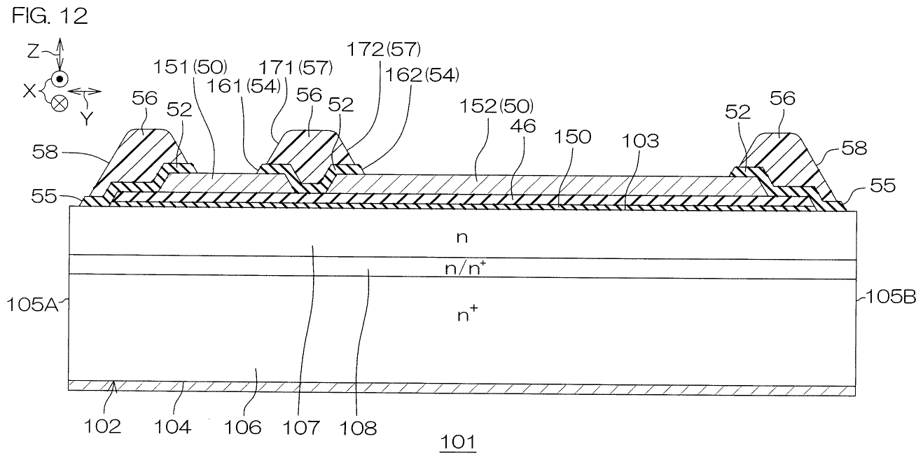

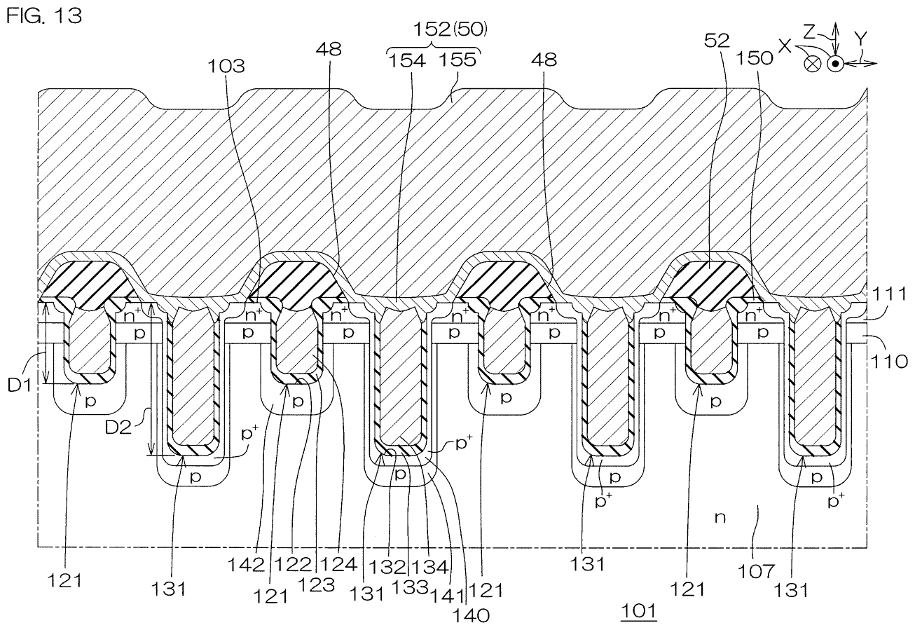

FIG. 11 is a plan view showing an SiC semiconductor device (hereinafter, referred to as “an SiC semiconductor device 101”) having a functional device according to another configuration example. FIG. 12 is a cross-sectional view along line XII-XII shown in FIG. 11. FIG. 13 is a cross-sectional view showing a principal portion of the functional device.

With reference to FIG. 11 to FIG. 13, the SiC semiconductor device 101 includes an SiC-MISFET as one example of the functional device. The SiC semiconductor device 101 includes an SiC chip 102. The SiC chip 102 is constituted of an individual piece of an SiC epi-wafer 41 and formed in a rectangular parallelepiped shape. The SiC chip 102 has a first main surface 103 on one side, a second main surface 104 on the other side and first to fourth side surfaces 105A to 105D which connect the first main surface 103 and the second main surface 104.

The first main surface 103 and the second main surface 104 are formed in a quadrilateral shape in a plan view as viewed in a normal direction Z thereto (hereinafter, refer to simply as “in a plan view”). The first main surface 103 and the second main surface 104 are formed in a quadrilateral shape in a plan view. The first main surface 103 and the second main surface 104 are arranged along c-planes of the SiC monocrystal. Preferably, the first main surface 103 is arranged along a silicon plane and the second main surface 104 is arranged along a carbon plane.

When the SiC epi-wafer 41 has an off angle, the first main surface 103 and the second main surface 104 each have an off angle corresponding to the off angle of the SiC epi-wafer 41. The second main surface 104 may be constituted of a rough surface that has one or both of a grinding mark and an annealing mark (specifically, a laser irradiation mark). The annealing mark may contain amorphized SiC and/or SiC (specifically, Si) that has been silicided (alloyed) with a metal (Ti).

The first to fourth side surfaces 105A to 105D form a peripheral edge of the first main surface 103 and a peripheral edge of the second main surface 104. The first side surface 105A and the second side surface 105B extend in a first direction X along the first main surface 103 and face each other in a second direction Y intersecting (specifically, orthogonal to) the first direction X. The third side surface 105C and the fourth side surface 105D extend in the second direction Y and face each other in the first direction X. In this embodiment, the first direction X is an m-axis direction ([1-100] direction) of an SiC monocrystal and the second direction Y is an a-axis direction of the SiC monocrystal.

The SiC semiconductor device 101 includes an n-type (first conductive type) first semiconductor region 106 which is formed in a surface layer portion of the second main surface 104. The first semiconductor region 106 forms a drain of an SiC-MISFET. The first semiconductor region 106 may be referred to as a drain region. The first semiconductor region 106 has an n-type impurity concentration that is substantially constant in the thickness direction. The first semiconductor region 106 is formed across an entire area of the surface layer portion of the second main surface 104 and has the second main surface 104 and portions of the first to fourth side surfaces 105A to 105D. The first semiconductor region 106 is formed of an n-type SiC substrate that is constituted of a portion of the SiC wafer 34.

The SiC semiconductor device 101 includes an n-type second semiconductor region 107 which is formed in the surface layer portion of the first main surface 103. The second semiconductor region 107 is electrically connected to the first semiconductor region 106 and forms the drain of the SiC-MISFET together with the first semiconductor region 106. The second semiconductor region 107 may be referred to as a drift region. The second semiconductor region 107 has an n-type impurity concentration less than an n-type impurity concentration of the first semiconductor region 106. The second semiconductor region 107 is formed across an entire area of the surface layer portion of the first main surface 103 and has the first main surface 103 and portions of the first to fourth side surfaces 105A to 105D. The second semiconductor region 107 is formed of an n-type SiC epitaxial layer 37.

The SiC semiconductor device 101 includes an n-type third semiconductor region 108 (concentration transition region) which is interposed between the first semiconductor region 106 and the second semiconductor region 107 in the SiC chip 102. The third semiconductor region 108 is electrically connected to the first semiconductor region 106 and the second semiconductor region 107 to form the drain of the SiC-MISFET, together with the first semiconductor region 106 and the second semiconductor region 107. The third semiconductor region 108 may be referred to as a buffer region.

The third semiconductor region 108 has a concentration gradient in which an n-type impurity concentration decreases (specifically, decreases gradually) from an n-type impurity concentration of the first semiconductor region 106 toward an n-type impurity concentration of the second semiconductor region 107. The third semiconductor region 108 is interposed over an entire area between the first semiconductor region 106 and the second semiconductor region 107 and has portions of the first to fourth side surfaces 105A to 105D. The third semiconductor region 108 is formed of the n-type epitaxial layer (SiC epitaxial layer 37).

The SiC semiconductor device 101 includes a p-type (second conductive type) body region 110 which is formed in the surface layer portion of the first main surface 103. The body region 110 forms a portion of a body diode of the SiC-MISFET.

The SiC semiconductor device 101 includes an n-type source region 111 which is formed in the surface layer portion of the body region 110. The source region 111 forms a source of the SiC-MISFET. The source region 111 has an n-type impurity concentration in excess of the n-type impurity concentration of the second semiconductor region 107. The source region 111 forms a channel of the SiC-MISFET inside the body region 110 together with the second semiconductor region 107.

The SiC semiconductor device 101 includes a plurality of trench gate structures 121 which are formed in the first main surface 103 such as to traverse the body region 110 and the source region 111 and reach the second semiconductor region 107. The plurality of trench gate structures 121 form a gate of the SiC-MISFET and control on/off of a channel. That is, the SiC-MISFET is constituted of a trench gate type.

The plurality of trench gate structures 121 are each formed in a band shape (rectangular shape) extending in the first direction X in a plan view and may be formed at an interval in the second direction Y. Each of the trench gate structures 121 is formed at an interval on the first main surface 103 side from a bottom portion of the second semiconductor region 107 and faces the first semiconductor region 106 (third semiconductor region 108) across a portion of the second semiconductor region 107. Each of the plurality of trench gate structures 121 has a first depth D1.

Each of the trench gate structures 121 includes a gate trench 122, agate insulating film 123 and a gate electrode 124. The gate trench 122 is formed in the first main surface 103 and forms a side wall and a bottom wall (inner wall and outer wall) of the trench gate structure 121. The gate insulating film 123 is formed as a film on an inner wall of the gate trench 122 and covers the second semiconductor region 107, the body region 110 and the source region 111. The gate electrode 124 is embedded in the gate trench 122 across the gate insulating film 123. The gate electrode 124 faces the second semiconductor region 107, the body region 110 and the source region 111 across the gate insulating film 123. Agate potential is imparted to the gate electrode 124.

The SiC semiconductor device 101 includes a plurality of trench source structures 131 which are formed in the first main surface 103 such as to traverse the body region 110 and the source region 111 and reach the second semiconductor region 107. The plurality of trench source structures 131 are each formed in a region between two trench gate structures 121 which are adjacent in the first main surface 103. The plurality of trench source structures 131 may be each formed in a band shape extending in the first direction X in a plan view. Each of the trench source structures 131 is formed at an interval on the first main surface 103 side from a bottom portion of the second semiconductor region 107 and faces the first semiconductor region 106 (third semiconductor region 108) across a portion of the second semiconductor region 107.

Each of the trench source structures 131 has a second depth D2 in excess of the first depth D1 of the trench gate structure 121 (D1<D2). The second depth D2 is preferably not less than 1.5 times and not more than 3 times the first depth D1. A bottom wall of each of the trench source structures 131 is positioned on the bottom portion side of the second semiconductor region 107 in relation to the bottom wall of each of the trench gate structures 121. As a matter of course, each of the trench source structures 131 may have a second depth D2(D1≈D2) which is substantially equal to the first depth D1.

Each of the trench source structures 131 includes a source trench 132, a source insulating film 133 and a source electrode 134. The source trench 132 is formed in the first main surface 103 and forms a side wall and a bottom wall (an inner wall and an outer wall) of the trench source structure 131. The source insulating film 133 is formed as a film on an inner wall of the source trench 132 and covers the second semiconductor region 107, the body region 110 and the source region 111. The source electrode 134 is embedded in the source trench 132 across the source insulating film 133. A source potential is applied to the source electrode 134.

The SiC semiconductor device 101 includes a plurality of p-type contact regions 140 which are each formed in a region along the plurality of trench source structures 131 in the surface layer portion of the first main surface 103. Each of the plurality of contact regions 140 has a p-type impurity concentration in excess of a p-type impurity concentration of the body region 110.

The plurality of contact regions 140 may be each formed in a multiple-to-one correspondence relationship with respect to each of the trench source structures 131 in a plan view. In this case, the plurality of contact regions 140 are formed at an interval along each of the trench source structures 131 in a plan view to partially expose each of the trench source structures 131. Each of the contact regions 140 may be formed in a band shape extending in the first direction X in a plan view. Each of the contact regions 140 covers the side wall and the bottom wall of each of the trench source structures 131 in the second semiconductor region 107 and is electrically connected to the body region 110.

The SiC semiconductor device 101 includes a plurality of p-type well regions 141 which are each formed in a region along the plurality of trench source structures 131 in the surface layer portion of the first main surface 103. The plurality of well regions 141 each have a p-type impurity concentration less than a p-type impurity concentration of each of the contact regions 140. The plurality of well regions 141 preferably have the p-type impurity concentration which exceeds the p-type impurity concentration of the body region 110.

The plurality of well regions 141 each cover the trench source structure 131 corresponding to the plurality of trench source structures 131 in a one-to-one correspondence relationship. Each of the well regions 141 may be formed in a band shape extending along a corresponding trench source structure 131. Each of the well regions 141 covers the side wall and the bottom wall of each trench source structure 131 and is electrically connected to the body region 110. Each of the well regions 141 may include a portion which directly covers each trench source structure 131 and a portion which covers each trench source structure 131 across the contact region 140.

The SiC semiconductor device 101 includes a plurality of p-type gate well regions 142 which are each formed in a region along the plurality of trench gate structures 121 in the surface layer portion of the first main surface 103. The plurality of gate well regions 142 have a p-type impurity concentration less than a p-type impurity concentration of the plurality of contact regions 140. Preferably, the p-type impurity concentration of each of the gate well regions 142 is substantially equal to the p-type impurity concentration of each of the well regions 141.

The plurality of gate well regions 142 may cover the trench gate structure 121 corresponding to the plurality of trench gate structures 121 in a one-to-one correspondence relationship. Each of the gate well regions 142 may be formed in a band shape extending along a corresponding trench gate structure 121. Each of the gate well regions 142 covers a side wall and a bottom wall of each of the trench gate structures 121 and is electrically connected to the body region 110. A bottom portion of the plurality of gate well regions 142 is positioned on the bottom wall side of the trench gate structure 121 with respect to a bottom portion of the plurality of well regions 141.

The SiC semiconductor device 101 includes a main surface insulating film 150 which covers the first main surface 103. The main surface insulating film 150 may have a single layer structure constituted of a silicon oxide film. The main surface insulating film 150 continues to the gate insulating film 123 and the source insulating film 133 and exposes the gate electrode 124 and the source electrode 134.

The SiC semiconductor device 101 includes a first inorganic insulating film 46 which is formed on the main surface insulating film 150. The first inorganic insulating film 46 selectively covers the plurality of trench gate structures 121 and the plurality of trench source structures 131. The first inorganic insulating film 46 has a plurality of contact openings 48 which selectively expose each of the plurality of trench gate structures 121 and each of the plurality of trench source structures 131.

The SiC semiconductor device 101 includes a first main surface electrode 50 which is formed on the first inorganic insulating film 46. The first main surface electrode 50 includes a gate main surface electrode 151, a source main surface electrode 152 and a gate wiring electrode 153. The gate main surface electrode 151 may be referred to as a gate pad electrode. The source main surface electrode 152 may be referred to as a source pad electrode. The gate wiring electrode 153 may be referred to as a gate finger electrode.

The gate main surface electrode 151 is electrically connected to the plurality of trench gate structures 121 (gate electrode 124) to impart an externally-input gate potential (gate signal) to the plurality of trench gate structures 121. In this embodiment, the gate main surface electrode 151 is arranged in a region which faces a central portion of the first side surface 105A in a peripheral edge portion of the first main surface 103. The gate main surface electrode 151 is formed in a quadrilateral shape having four sides parallel to the first main surface 103 in a plan view.

The source main surface electrode 152 is arranged on the first main surface 103 at an interval from the gate main surface electrode 151. The source main surface electrode 152 is electrically connected to the plurality of trench source structures 131 (source electrode 134) to impart an externally-input source potential to the plurality of trench source structures 131. In this embodiment, the source main surface electrode 152 is formed in a quadrilateral shape having four sides parallel to the first main surface 103 in a plan view.

Specifically, the source main surface electrode 152 is formed in a polygonal shape having a recess portion that is depressed toward an inner portion of the first main surface 103 such as to conform to the gate main surface electrode 151 at the side along the first side surface 105A in a plan view. The source main surface electrode 152 enters into the plurality of contact openings 48 from above the first inorganic insulating film 46 and is electrically connected to the plurality of trench source structures 131, the plurality of source regions 111 and the plurality of contact regions 140.

The gate wiring electrode 153 is led out from the gate main surface electrode 151 onto the first inorganic insulating film 46. The gate wiring electrode 153 transmits a gate potential applied to the gate main surface electrode 151 to other regions. The gate wiring electrode 153 is formed in a band shape extending along the first to fourth side surfaces 105A to 105D in a plan view and faces the source main surface electrode 152 from a plurality of directions.

The gate wiring electrode 153 intersects (specifically, orthogonal to) an end portion of the trench gate structure 121 in a plan view. The gate wiring electrode 153 enters into the plurality of contact openings 48 from above the first inorganic insulating film 46 and is electrically connected to the plurality of trench gate structures 121 (gate electrode 124). Thereby, a gate potential applied to the gate main surface electrode 151 is imparted to the plurality of trench gate structures 121 via the gate wiring electrode 153.

The first main surface electrodes 50 each have a laminated structure which includes a first electrode film 154 and a second electrode film 155 laminated in that order from the first inorganic insulating film 46 side. The first electrode film 154 is constituted of a metal barrier film that is formed as a film along the first inorganic insulating film 46. In this embodiment, the first electrode film 154 is constituted of a Ti-based metal film. The first electrode film 154 may include at least one of a titanium film and a titanium nitride film.

The second electrode film 155 is formed as a film along the first electrode film 154. The first electrode film 154 is constituted of a Cu-based metal film or an Al-based metal film. The first electrode film 154 may include at least one film among a pure Cu film, a pure Al film, an AlCu alloy film, an AlSi alloy film and an AlSiCu alloy film.

The SiC semiconductor device 101 includes a second inorganic insulating film 52 which selectively covers the first main surface 103, the first inorganic insulating film 46 and the first main surface electrode 50. The second inorganic insulating film 52 has a plurality of first pad openings 54 which expose the first main surface electrode 50. The plurality of first pad openings 54 include a first gate pad opening 161 and a first source pad opening 162.

The first gate pad opening 161 selectively exposes an inner portion of the gate main surface electrode 151. The first source pad opening 162 selectively exposes an inner portion of the source main surface electrode 152. The second inorganic insulating film 52 has a first dicing street 55 which exposes a peripheral edge portion of the first main surface 103 together with a peripheral edge of the first main surface 103. The first dicing street 55 is demarcated in a quadrilateral annular shape extending along the peripheral edge of the first main surface 103.

The SiC semiconductor device 101 includes an organic insulating film 56 which selectively covers the first inorganic insulating film 46, the second inorganic insulating film 52 and the first main surface electrode 50. The organic insulating film 56 has a plurality of second pad openings 57. The plurality of second pad openings 57 include a second gate pad opening 171 and a second source pad opening 172.

The second gate pad opening 171 is communicatively connected to the first gate pad opening 161 and exposes an inner portion of the gate main surface electrode 151. The second source pad opening 172 is communicatively connected to the first source pad opening 162 and exposes an inner portion of the source main surface electrode 152. The organic insulating film 56 has a second dicing street 58 which exposes the peripheral edge portion of the first main surface 103 together with the first dicing street 55. The second dicing street 58 is demarcated in a quadrilateral annular shape extending along the peripheral edge of the first main surface 103.

The SiC semiconductor device 101 includes a second main surface electrode 71 which covers the second main surface 104. The second main surface electrode 71 may be referred to as a drain electrode. The second main surface electrode 71 covers an entire area of the second main surface 104 and continues to the peripheral edge (the first to fourth side surfaces 105A to 105D) of the first main surface 103. The second main surface electrode 71 forms an ohmic contact with the first semiconductor region 106 (second main surface 104).

In FIG. 11 to FIG. 13, a description has been given of an example in which the SiC-MISFET has the trench gate structure 121 and the trench source structure 131. However, there may be adopted an SiC-MISFET which does not have the trench source structure 131. Further, in FIG. 11 to FIG. 13, a description has been given of the trench gate type SiC-MISFET. However, there may be adopted a planar gate type SiC-MISFET.

Examples of features extracted from the present description and drawings are indicated below.

[A1] A semiconductor device manufacturing method comprising: a step which prepares a wafer source and a supporting member; a supporting step which supports the wafer source by the supporting member; and a wafer separating step in which the wafer source is cut in a horizontal direction from a thickness direction intermediate portion of the wafer source to separate from the wafer source a wafer structure that includes the supporting member and a wafer cut away from the wafer source.

[A2] The semiconductor device manufacturing method according to A1, wherein the wafer source cut out from an ingot is prepared.

[A3] The semiconductor device manufacturing method according to A1 or A2, further comprising: a step which transfers the wafer structure.

[A4] The semiconductor device manufacturing method according to any one of A1 to A3, further comprising: a wafer source reusing step in which a series of steps including the supporting step and the wafer separating step are repeated until the wafer source becomes unable to be separated.

[A5] The semiconductor device manufacturing method according to any one of A1 to A4, wherein the wafer source cutting step includes a step that, after a modified layer along the horizontal direction is formed in the thickness direction intermediate portion of the wafer source by a laser light irradiation method, the wafer source is cleaved in the horizontal direction with the modified layer as a starting point.

[A6] The semiconductor device manufacturing method according to any one of A1 to A5, further comprising: a step which forms an epitaxial layer in a section plane of the wafer.

[A7] The semiconductor device manufacturing method according to A6, further comprising: a step of polishing the section plane; wherein the epitaxial layer is formed in a polished surface of the wafer.

[A8] The semiconductor device manufacturing method according to any one of A1 to A5, further comprising: a step of forming a functional device in the section plane of the wafer.

[A9] The semiconductor device manufacturing method according to A8, further comprising: a step of polishing the section plane; wherein the functional device is formed in the polished surface of the wafer.

[A10] The semiconductor device manufacturing method according to A8 or A9, further comprising: a step that removes the supporting member from the wafer after formation of the functional device.

[A11] The semiconductor device manufacturing method according to any one of A1 to A10, wherein the supporting member is constituted of the same material as the wafer source.

[A12] The semiconductor device manufacturing method according to A11, wherein the wafer source is constituted of an SiC monocrystal and the supporting member is constituted of an SiC monocrystal or an SiC polycrystal.

[A13] The semiconductor device manufacturing method according to any one of A1 to A12, wherein the supporting member is bonded to the wafer source by a direct bonding method.

[A14] A semiconductor device manufacturing method comprising: a step which prepares a first semiconductor and a second semiconductor; a step in which the second semiconductor is bonded to the first semiconductor by a direct bonding method to form a semiconductor structure having an amorphous bonding layer between the first semiconductor and the second semiconductor; a step which forms a modified layer in the amorphous bonding layer by a laser light irradiation method; and a step which cleaves the semiconductor structure with the modified layer as a starting point and separates the first semiconductor and the second semiconductor.

[A15] The semiconductor device manufacturing method according to A14, wherein the amorphous bonding layer having a light absorption coefficient larger than a light absorption coefficient of the first semiconductor is formed.

[A16] The semiconductor device manufacturing method according to A14 or A15, wherein the first semiconductor is constituted of an SiC monocrystal, the second semiconductor is constituted of an SiC monocrystal or an SiC polycrystal, and the amorphous bonding layer is constituted of an SiC amorphous bonding layer.

[B1] An SiC semiconductor device manufacturing method, comprising: a step which prepares an SiC wafer source having a silicon plane and a carbon plane, a supporting step which supports the SiC wafer source from the carbon plane side by a supporting member, and a wafer separating step in which the SiC wafer source is cut in a horizontal direction from a thickness direction intermediate portion of the SiC wafer source along the silicon plane to separate, from the SiC wafer source, an SiC wafer structure that includes the supporting member and an SiC wafer cut away from the SiC wafer source.

[B2] The SiC semiconductor device manufacturing method according to B1, wherein the SiC wafer structure includes the SiC wafer having a section plane that is arranged along the silicon plane.

[B3] The SiC semiconductor device manufacturing method according to B1 or B2, wherein the SiC wafer source cut out from an SiC ingot is prepared.

[B4] The SiC semiconductor device manufacturing method according to any one of B1 to B3, further comprising: a step which transfers the SiC wafer structure.

[B5] The SiC semiconductor device manufacturing method according to any one of B1 to B4, further comprising: an SiC wafer source reusing step in which a series of steps including the supporting step and the wafer separating step are repeated until the SiC wafer source becomes unable to be separated.

[B6] The SiC semiconductor device manufacturing method according to any one of B1 to B5, wherein the step of cutting the SiC wafer source includes a step that, after a modified layer along the horizontal direction is formed in the thickness direction intermediate portion of the SiC wafer source by a laser light irradiation method, the SiC wafer source is cleaved in the horizontal direction with the modified layer as a starting point.

[B7] The SiC semiconductor device manufacturing method according to any one of B1 to B6, further comprising: a step of forming an SiC epitaxial layer in a section plane of the SiC wafer.

[B8] The SiC semiconductor device manufacturing method according to B7, further comprising: a step of polishing the section plane; wherein the SiC epitaxial layer is formed in the polished surface of the SiC wafer.

[B9] The SiC semiconductor device manufacturing method according to any one of B1 to B6, further comprising: a step of forming a functional device in the section plane of the SiC wafer.

[B10] The SiC semiconductor device manufacturing method according to B9, further comprising: a step of polishing the section plane; wherein the functional device is formed in the polished surface of the SiC wafer.

[B11] The SiC semiconductor device manufacturing method according to B9 or B10, further comprising: a step of removing the supporting member from the SiC wafer after formation of the functional device.

[B12] The SiC semiconductor device manufacturing method according to any one of B9 to B11, wherein the functional device includes at least one of an SBD and a MISFET.

[B13] The SiC semiconductor device manufacturing method according to any one of B1 to B12, wherein the supporting member is constituted of an SiC-made SiC supporting wafer.

[B14] The SiC semiconductor device manufacturing method according to any one of B1 to B13, wherein the supporting member is bonded to the carbon plane by a direct bonding method.

[B15] An SiC semiconductor device manufacturing method comprising: a step which prepares a first SiC and a second SiC; a step in which the second SiC is bonded to the first SiC by a direct bonding method to form an SiC structure having an SiC amorphous bonding layer between the first SiC and the second SiC; a step in which the amorphous bonding layer is irradiated with laser light to form a modified layer in the amorphous bonding layer; and a step which cleaves the SiC structure with the modified layer as a starting point and separates the first SiC and the second SiC.

[B16] The SiC semiconductor device manufacturing method according to B15, wherein the amorphous bonding layer having a light absorption coefficient larger than a light absorption coefficient of SiC is formed.

[C1] An SiC wafer source processing method comprising: a step which prepares an SiC wafer source having a silicon plane and a carbon plane; a supporting step which supports the SiC wafer source from the carbon plane side by a supporting member; and a wafer separating step in which the SiC wafer source is cut in a horizontal direction along the silicon plane from a thickness direction intermediate portion of the SiC wafer source and separates, from the SiC wafer source, an SiC wafer structure that includes the supporting member and an SiC wafer cut away from the SiC wafer source.

[C2] The SiC wafer source processing method according to C1, wherein the SiC wafer structure includes the SiC wafer having a section plane that is arranged along the silicon plane.

[C3] The SiC wafer source processing method according to C2, further comprising: a step of polishing the section plane of the SiC wafer.

[C4] The SiC wafer source processing method according to any one of C1 to C3, wherein the supporting member is constituted of an SiC-made SiC supporting wafer.

[C5] The SiC wafer source processing method according to any one of C1 to C4, wherein the supporting member is bonded to the carbon plane by a direct bonding method.

[C6] The SiC wafer source processing method according to C5, wherein the supporting member is bonded to the carbon plane by an SiC amorphous bonding layer and the SiC wafer structure includes the SiC amorphous bonding layer between the supporting member and the SiC wafer.

[C7] The SiC wafer source processing method according to C6, wherein the SiC amorphous bonding layer having a light absorption coefficient larger than a light absorption coefficient of SiC is formed.

[C8] The SiC wafer source processing method according to C6 or C7, further comprising: a step in which the SiC amorphous bonding layer is irradiated with laser light to form a modified layer in the SiC amorphous bonding layer and a step which cleaves the SiC wafer structure with the modified layer as a starting point and separates the supporting member and the SiC wafer.

[D1] A wafer structure comprising: a first wafer; a second wafer which supports the first wafer; and an amorphous bonding layer which is interposed between the first wafer and the second wafer and bonds the first wafer and the second wafer.

[D2] The wafer structure according to D1, wherein the amorphous bonding layer has a light absorption coefficient larger than a light absorption coefficient of the second wafer.

[D3] The wafer structure according to D1 or D2, wherein the first wafer is constituted of a monocrystal of a wide bandgap semiconductor, the second wafer is constituted of a monocrystal or a polycrystal of a wide bandgap semiconductor, and the amorphous bonding layer is constituted of an amorphous layer of a wide bandgap semiconductor.

[D4] The wafer structure according to any one of D1 to D3, wherein the first wafer is constituted of an SiC monocrystal, the second wafer is constituted of an SiC monocrystal or an SiC polycrystal, and the amorphous bonding layer is constituted of an SiC amorphous bonding layer.

[D5] The wafer structure according to D4, wherein the first wafer has a first main surface which is formed of a silicon plane of an SiC monocrystal and a second main surface which is formed of a carbon plane of the SiC monocrystal, the second wafer has a third main surface which is formed of a silicon plane of an SiC monocrystal to support the first wafer from the second main surface side and a fourth main surface which is formed of a carbon plane of the SiC monocrystal, and the amorphous bonding layer is interposed between the second main surface of the first wafer and the third main surface of the second wafer.

[D6] The wafer structure according to D5, wherein the first main surface has an off angle of not more than 10° with an a-axis direction of the SiC monocrystal as an off direction.

[D7] The wafer structure according to D5 or D6, wherein the first main surface is constituted of a cleavage surface, a ground surface, a polished surface or a mirror-finished surface.

[D8] The wafer structure according to any one of D1 to D7, wherein the amorphous bonding layer has a thickness of not more than 5 μm.

[D9] The wafer structure according to any one of D1 to D8, wherein the first wafer is formed in a disk shape or a cylindrical shape, and the second wafer is formed in a disk shape or a cylindrical shape.

[D10] The wafer structure according to any one of D1 to D9, wherein the second wafer has a plane area larger than a plane area of the first wafer.

[D11] The wafer structure according to any one of D1 to D10, wherein the second wafer is thicker than the first wafer.

[D12] The wafer structure according to any one of D1 to D11, wherein the second wafer has an impurity concentration different from the first wafer.

[D13] The wafer structure according to D12, wherein the second wafer has an impurity concentration less than an impurity concentration of the first wafer.

[D14] The wafer structure according to D12 or D13, wherein the second wafer is not doped with an impurity.

[D15] The wafer structure according to any one of D1 to D14, wherein the first wafer includes a first mark which indicates a crystal orientation, and the second wafer includes a second mark which indirectly indicates the crystal orientation of the first wafer.

[D16] The wafer structure according to D15, wherein the first mark includes one or both of a first orientation flat and a first orientation notch, and the second mark includes one or both of a second orientation flat and a second orientation notch.

[D17] An SiC wafer structure comprising: a first SiC wafer which has a first main surface on one side and a second main surface on the other side; a second SiC wafer which supports the first SiC wafer from the second main surface side; and an amorphous bonding layer which is interposed between the first SiC wafer and the second SiC wafer and bonds the first SiC wafer and the second SiC wafer.

[D18] The SiC wafer structure according to D17, wherein the amorphous bonding layer has a light absorption coefficient larger than a light absorption coefficient of the second SiC wafer.

[D19] The SiC wafer structure according to D17 or D18, wherein the second SiC wafer has a diameter larger than that of the first SiC wafer.

[D20] The SiC wafer structure according to any one of D17 to D19, wherein the amorphous bonding layer contains at least carbon.

While preferred embodiments of the present invention were described in detail above, these are merely specific examples used to clarify the technical contents of the present invention and the present invention should not be interpreted as being limited to these specific examples and the scope of the present invention is limited only by the appended claims.

### REFERENCE SIGNS LIST

1 SiC wafer source
21 second supporting member
32 second amorphous bonding layer
33 modified layer
34 SiC wafer
35 SiC wafer structure
36 section plane
37 SiC epitaxial layer
70 modified layer

1. A semiconductor device manufacturing method comprising:
a step which prepares a wafer source and a supporting member;
a supporting step which supports the wafer source by the supporting member; and
a wafer separating step in which the wafer source is cut in a horizontal direction from a thickness direction intermediate portion of the wafer source to separate, from the wafer source, a wafer structure that includes the supporting member and a wafer cut away from the wafer source.

2. The semiconductor device manufacturing method according to claim 1,
wherein the wafer source cut out from an ingot is prepared.

3. The semiconductor device manufacturing method according to claim 1, further comprising:
a step which transfers the wafer structure.

4. The semiconductor device manufacturing method according to any claim 1, further comprising:
a wafer source reusing step in which a series of steps including the supporting step and the wafer separating step are repeated until the wafer source becomes unable to be separated.

5. The semiconductor device manufacturing method according to claim 1,
wherein the cutting step of the wafer source includes a step in which, after a modified layer along the horizontal direction is formed in the thickness direction intermediate portion of the wafer source by a laser light irradiation method, the wafer source is cleaved in the horizontal direction with the modified layer as a starting point.

6. The semiconductor device manufacturing method according to claim 1, further comprising:
a step which forms an epitaxial layer in a section plane of the wafer.

7. The semiconductor device manufacturing method according to claim 6, further comprising:
a step which polishes the section plane;
wherein the epitaxial layer is formed on the polished surface of the wafer.

8. The semiconductor device manufacturing method according to claim 1, further comprising:
a step which forms a functional device in the section plane of the wafer.

9. The semiconductor device manufacturing method according to claim 8, further comprising:
a step which polishes the section plane;
wherein the functional device is formed in the polished surface of the wafer.

10. The semiconductor device manufacturing method according to claim 8, further comprising:
a step which removes the supporting member from the wafer after formation of the functional device.

11. The semiconductor device manufacturing method according to claim 1,
wherein the supporting member is constituted of the same material as the wafer source.

12. The semiconductor device manufacturing method according to claim 11,
wherein the wafer source is constituted of an SiC monocrystal, and
the supporting member is constituted of an SiC monocrystal or an SiC polycrystal.

13. The semiconductor device manufacturing method according to claim 1,
wherein the supporting member is bonded to the wafer source by a direct bonding method.

14. A semiconductor device manufacturing method comprising:
a step which prepares a first semiconductor and a second semiconductor;
a step in which the second semiconductor is bonded to the first semiconductor by a direct bonding method to form a semiconductor structure which has an amorphous bonding layer between the first semiconductor and the second semiconductor;
a step which forms a modified layer in the amorphous bonding layer by a laser light irradiation method; and
a step which cleaves the semiconductor structure with the modified layer as a starting point and separates the first semiconductor and the second semiconductor.

15. The semiconductor device manufacturing method according to claim 14,
wherein the amorphous bonding layer which has a light absorption coefficient larger than a light absorption coefficient of the first semiconductor is formed.

16. The semiconductor device manufacturing method according to claim 14,
wherein the first semiconductor is constituted of an SiC monocrystal,
the second semiconductor is constituted of an SiC monocrystal or an SiC polycrystal, and
the amorphous bonding layer is constituted of an SiC amorphous bonding layer.

17. A wafer structure comprising:
a first wafer;
a second wafer which supports the first wafer; and
an amorphous bonding layer which is interposed between the first wafer and the second wafer and bonds the first wafer and the second wafer.

18. The wafer structure according to claim 17,
wherein the amorphous bonding layer has a light absorption coefficient larger than a light absorption coefficient of the second wafer.

19. The wafer structure according to claim 17,
wherein the second wafer has a diameter larger than that of the first wafer.

20. The wafer structure according to claim 17,
wherein the first wafer is constituted of an SiC monocrystal,
the second wafer is constituted of an SiC monocrystal or an SiC polycrystal, and
the amorphous bonding layer is constituted of an SiC amorphous bonding layer.
